(19) United States
(12) Patent Application Publication
(10) Pub. No.: US 2026/0221388 A1
(43) Pub. Date: Jul. 30, 2026

(54) Enhanced Tuning of Pulse Waveforms Via Secondary Level Feedforward Tuning

(71) Applicant: MKS, Inc., Andover, MA (US)

(72) Inventors: Aaron BURRY, Rochester, NY (US); Peter PAUL, Rochester, NY (US); Aaron RADOMSKI, Rochester, NY (US)

(21) Appl. No.: 19/041,111

(22) Filed: Jan. 30, 2025

(51) Int. Cl. H01J 37/32

(52) U.S. Cl. CPC H01J 37/32146; H01J 37/32183

(57) ABSTRACT

A controller for controlling a power generator including a power controller coupled to a power source. The power controller generates a control signal to vary an output signal pulsed over a plurality of pulse states. The power controller is further configured to adjust at least one parameter of the output signal that determines a characteristic of the output signal for at least one pulse state. The at least one parameter is controlled with a primary adjustment and at least one secondary adjustment, wherein the at least one secondary adjustment varies the primary adjustment.

### FIELD

The present disclosure relates to RF generator systems and to control of RF generators.

### BACKGROUND

Plasma processing is frequently used in semiconductor fabrication. In plasma processing, ions are accelerated by an electric field to etch material from or deposit material onto a surface of a substrate. In one basic implementation, the electric field is generated based on Radio Frequency (RF) or Direct Current (DC) power signals generated by a respective RF or DC generator of a power delivery system. The power signals generated by the generator must be precisely controlled to effectively execute plasma etching.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a controller for a power generator. The controller includes a power controller coupled to a power source, the power controller configured to generate a control signal to vary an output signal pulsed over a plurality of pulse states, and the power controller configured to adjust at least one parameter of the output signal that determines a characteristic of the output signal for at least one pulse state. The at least one parameter is controlled with a primary adjustment and at least one secondary adjustment, where the at least one secondary adjustment varies the primary adjustment. Other embodiments of this aspect include corresponding computer systems, apparatus, and computer programs recorded on one or more computer storage devices, each configured to perform the actions of the methods.

Implementations may include one or more of the following features. The controller where the at least one parameter is controlled in accordance with one of minimizing or maximizing a cost function responsive to adjustment of the at least one parameter, where the at least one parameter includes at least one of frequency, voltage, or impedance. The at least one secondary adjustment varies the primary adjustment within a selected pulse state for each a plurality of adjacent pulse states, within a selected pulse state for each of a plurality of nonadjacent pulse states, over a plurality of pulse states adjacent pulse states, or over a plurality of nonadjacent pulse states. The at least one secondary adjustment may be the same for a plurality of selected pulse states, or the at least one secondary adjustment may be different for each of a plurality of selected pulse states. The at least one secondary adjustment further may include a plurality of secondary adjustments, where the plurality of secondary adjustments varies the primary adjustment within a selected pulse state or the plurality of secondary adjustments varies the primary adjustment over a plurality of pulse states. The primary adjustment is formed by a first basis set and the at least one secondary adjustment is formed by a second basis set. The power source provides an output signal that may be one of a sinusoidal signal, square wave signal, rectangular wave signal, triangular signal, gaussian signal, piecewise linear signal, narrow pulse voltage peak followed by a ramp down signal, or an arbitrary signal. Implementations of the described techniques may include hardware, a method or process, or computer software on a computer-accessible medium.

One general aspect includes a power generator system having a power source, the power source generating a time-varying output signal to a load. The system includes a power controller coupled to the power source, the power controller configured to generate a control signal to vary an output signal pulsed over a plurality of pulse states, and the power controller configured to adjust at least one parameter of the output signal that determines a characteristic of the output signal for at least one pulse state. The system also includes a primary tuner configured to provide a first adjustment to the at least one parameter. The system also includes at least one secondary tuner configured to apply at least one second adjustment to the first adjustment. The at least one parameter is adjusted by the primary tuner and the at least one secondary tuner in accordance with one of minimizing or maximizing a cost function responsive to adjustment of the at least one parameter. Other embodiments of this aspect include corresponding computer systems, apparatus, and computer programs recorded on one or more computer storage devices, each configured to perform the actions of the methods.

Implementations may include one or more of the following features. The power generator system where the at least one secondary tuner varies applies at least one second adjustment: within a selected pulse state for each of a plurality of adjacent pulse states, within a selected pulse state for each of a plurality of nonadjacent pulse states, over a plurality of pulse states adjacent pulse states, or over a plurality of nonadjacent pulse states. The at least one secondary tuner may apply a same at least one second adjustment to a plurality of selected pulse states, or the at least one secondary tuner may apply a different at least one second adjustment for each of the plurality of selected pulse states. The at least one secondary tuner further applies a plurality of at least one second adjustments, where: the plurality of at least one second adjustments varies the first adjustment within a selected pulse state; or the plurality of at least one second adjustments varies the first adjustment over a plurality of pulse states. The first adjustment is formed from a first basis set and the at least one second adjustment is formed by at least one second basis set. The power source provides an output signal that may be one of a sinusoidal signal, square wave signal, rectangular wave signal, triangular signal, gaussian signal, piecewise linear signal, narrow pulse voltage peak followed by a ramp down signal, or an arbitrary signal. The at least one secondary adjustment may be the same for a plurality of selected pulse states, or the at least one secondary adjustment may be different for each of a plurality of selected pulse states. Implementations of the described techniques may include hardware, a method or process, or computer software on a computer-accessible medium.

One general aspect includes a non-transitory computer-readable medium storing instructions. The non transitory computer readable medium storing instructions also includes generating a control signal to vary an output signal pulsed over a plurality of pulse states. The instructions also include adjusting at least one parameter of the output signal that determines a characteristic of the output signal for at least one pulse state. The instructions also include controlling the at least one parameter with a primary adjustment. The instructions also include further controlling the at least one parameter with at least one secondary adjustment, where the at least one secondary adjustment varies the primary adjustment. Other embodiments of this aspect include corresponding computer systems, apparatus, and computer programs recorded on one or more computer storage devices, each configured to perform the actions of the methods.

Implementations may include one or more of the following features. The non-transitory computer-readable medium storing instructions where the at least one parameter is controlled in accordance with one of minimizing or maximizing a cost function responsive to adjustment of the at least one parameter, wherein the at least one parameter includes at least one of frequency, voltage, or impedance. The at least one secondary adjustment varies the primary adjustment: within a selected pulse state for each a plurality of adjacent pulse states, within a selected pulse state for each of a plurality of nonadjacent pulse states, over a plurality of pulse states adjacent pulse states, or over a plurality of nonadjacent pulse states. The at least one secondary adjustment further may include a plurality of secondary adjustments, where: the plurality of secondary adjustments varies the primary adjustment within a selected pulse state; or the plurality of secondary adjustments varies the primary adjustment over a plurality of pulse states. The primary adjustment is formed by a first basis set and the at least one secondary adjustment is formed by a second basis set. The power source provides an output signal that may be one of a sinusoidal signal, square wave signal, rectangular wave signal, triangular signal, gaussian signal, piecewise linear signal, narrow pulse voltage peak followed by a ramp down signal, or an arbitrary signal. Implementations of the described techniques may include hardware, a method or process, or computer software on a computer-accessible medium.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 shows a generalized representation of a plasma system arranged according to various configurations of the present disclosure;

FIG. 2 shows an example plot of reflected or reverse intermodulation distortion (IMD) resulting from applying two signals of different frequency to a nonlinear reactor;

FIG. 3 shows voltage and power waveforms for a system having RF signals applied to a load and the effect of intermodulation distortion on power delivery to the load;

FIG. 4 shows waveforms that depict the effect of a frequency offset or hopping pattern on power delivered to a load for one state of a pulsed signal;

FIG. 5 is a schematic block diagram of a power delivery system having multiple power supplies arranged according to various configurations of the present disclosure;

FIG. 6 shows waveforms of a time-varying signal and a pulse modulating the time-varying signal to describe a pulse mode of operation;

FIGS. 7A-7D show waveforms of a carrier signal and a pulse modulating the carrier signal to describe a pulsed DC mode of operation and various waveforms for the carrier signal of FIG. 7A;

FIG. 8 shows a relationship between normalized coefficients of multiple bins of a single pulse state in full profile and a Fourier series basis function for a many-to-fewer correspondence between each bin and a basis function index;

FIG. 9 shows an example secondary scaling of one Fourier component of a frequency offset or hopping pattern of FIG. 8 according to the present disclosure;

FIG. 10 is a partial schematic block diagram of a controller for a power delivery system applying two layers of basis functions for determining a frequency offset or hopping pattern;

FIG. 11 is a partial schematic block diagram of a controller for a power delivery system applying multiple layers of basis functions for determining a frequency offset or hopping pattern;

FIG. 12 shows a functional block diagram of an example control module arranged in accordance with various configurations;

FIG. 13 shows a flow chart of operation of a control system arranged in accordance with the principles of the present disclosure.

FIG. 14 shows another flow chart of operation of a control system arranged in accordance with the principals of the present disclosure;

FIG. 15A-15C show example basis weights and corresponding primary or low-level scaling according to the present disclosure; and

FIG. 16A-16C show example basis weights and corresponding low-level and high-level scaling according to the present disclosure.

In the drawings, reference numbers may be reused to identify similar and/or identical elements.

### DETAILED DESCRIPTION

A power system may include a DC or RF power generator or DC or RF generator, collectively referred to as generator or generators, a matching network, and a load (such as a process chamber, a plasma chamber, or a reactor having a fixed or variable impedance). The generator generates a DC power signal or a sinusoidal, RF, or other time-varying signal, which is received by the matching network or impedance optimizing controller or circuit. The matching network or impedance optimizing controller or circuit transforms a load impedance to a characteristic impedance of a transmission line between the generator and the matching network. Impedance matching aids in maximizing an amount of power delivered to the load (“delivered power”) and minimizing an amount of power reflected back from the load to the generator (“reverse power” or “reflected power”). Delivered power may be maximized by minimizing reflected power when the input impedance of the matching network matches the characteristic impedance of the transmission line and generator.

In the power source or power supply field, there are typically two approaches to applying a power signal to the load. A first, more traditional approach is to apply a continuous voltage, current, or power signal to the load. In a continuous mode or continuous wave mode, a continuous voltage, current, or power signal is typically a constant DC, sinusoidal, or periodic time-varying signal, which may be a RF or other voltage, current, or power signal, that is output continuously by the power source to the load. In the continuous mode approach, the voltage, current, or power signal assumes a constant DC or sinusoidal output, and the amplitude of the power signal and/or frequency (of a RF power signal) can be varied in order to vary the output power applied to the load.

A second approach to applying the power signal to the load involves pulsing a voltage, current, or power signal, rather than applying a continuous voltage, current, or power signal to the load. In a pulse or pulsed mode of operation, a voltage, current, or power signal or carrier signal is modulated by a modulation signal in order to define an envelope for the modulated power signal. The voltage, current, or power signal may be, for example, a sinusoidal RF signal or other periodic or nonperiodic time-varying signal. Power delivered to the load is typically varied by varying the modulation signal. In a pulsed mode of operation of a pulsed DC signal, the voltage, current, or power signal may be a periodic or nonperiodic DC signal that alternates between at least a first amplitude and a second amplitude over one or more cycles and modulated by a modulation signal in order to define an envelope for the pulsed DC signal. In various configurations, a transition between the first amplitude and the second amplitude may include various shapes, including vertical slopes, nonvertical slopes, or combinations thereof, stair steps, and the like. Further the transition between the first amplitude and the second, or the second amplitude and the first amplitude, may be consistent or vary from cycle-to-cycle.

In one various power supply configuration, output voltage, current, or power applied to the load is determined using sensors that measure the forward and reflected voltage, current, or power signal. Either set of these signals is analyzed in a control loop. The analysis typically determines a parameter or a cost function that varies in accordance with a voltage, current, or power value and is used to adjust the output of the power supply in order to vary the voltage, current, or power applied to the load. In a power delivery system where the load is a process chamber or other nonlinear or time-varying load, the varying impedance of the load causes a corresponding varying of voltage, current, or power applied to the load and consequent varying of the parameter or cost function, as applied voltage, current, or power is in part a function of the impedance of the load.

In systems where fabrication of various devices relies upon introduction of voltage, current, or power to a load to control a fabrication process, voltage, current, or power is typically delivered in one of two configurations. In a first configuration, voltage, current, or power is capacitively coupled to the load. Such systems are referred to as capacitively coupled plasma (CCP) systems. In a second configuration, the voltage, current, or power is inductively coupled to the load. Such systems are typically referred to as inductively coupled plasma (ICP) systems. Coupling to the plasma can also be achieved via wave coupling at microwave frequencies. Such an approach typically uses Electron Cyclotron Resonance (ECR) or microwave sources. Helicon sources are another form of wave coupled sources and typically operate at frequencies similar to that of conventional ICP and CCP systems. In various configurations, the Helicon sources may operate at RF frequencies.

Power delivery systems may include at least one bias power and/or a source power applied to one or a plurality of electrodes of the load. The source power typically generates a plasma and controls plasma density, and the bias power modulates ions in the formulation of the sheath. The bias and the source may share the same electrode or may use separate electrodes, in accordance with various design considerations.

When a power delivery system drives a time-varying or nonlinear load, such as a process chamber or plasma chamber, the power absorbed by the bulk plasma and plasma sheath results in a density of ions with a range of ion energy. One characteristic measure of ion energy is the ion energy distribution function (IEDF). The ion energy distribution function (IEDF) can be controlled with the bias power or voltage. One way of controlling the IEDF for a system in which multiple voltage, current, or power signals are applied to the load occurs by varying multiple voltage, current, or power signals that are related by at least one of amplitude, frequency, and phase. The related at least one of amplitude, frequency, and phase of multiple voltage, current, or power signals may also be related by a Fourier series and the associated coefficients. The frequencies between the multiple voltage, current, or power signals may be locked, and the relative phase between the multiple voltage, current, or signals may also be locked. Examples of such systems can be found with reference to U.S. Pat. No. 7,602,127, issued Oct. 13, 2009; U.S. Pat. No. 8,110,991, issued Feb. 7, 2012; and U.S. Pat. No. 8,395,322, issued Mar. 12, 2013, all entitled Phase and Frequency Control of a Radio Frequency Generator from an External Source, assigned to the assignee of the present application, and incorporated by reference herein.

Time varying or nonlinear loads may be present in various applications. In one application, plasma processing systems may also include components for plasma generation and control. One such component is a nonlinear load implemented as a process chamber, such as a plasma chamber or reactor. A typical plasma chamber or reactor utilized in plasma processing systems, such as by way of example, for thin-film manufacturing, can utilize a dual power system. One voltage, current, or power generator (the source) controls the generation of the plasma, and the other voltage, current, or power generator (the bias) controls ion energy. Examples of dual power systems include systems that are described in U.S. Pat. No. 7,602,127; U.S. Pat. No. 8,110,991; and U.S. Pat. No. 8,395,322, referenced above. The dual power system described in the above-referenced patents employs a closed-loop control system to adapt power supply operation for the purpose of controlling ion density and its corresponding ion energy distribution function (IEDF).

Multiple approaches exist for controlling a process chamber, such as may be used for generating plasmas. For example, in voltage, current, or power delivery systems, phase and frequency of multiple driving signals operating at the same or nearly the same frequency may be used to control plasma generation. For such driven plasma sources, the periodic waveform affecting plasma sheath dynamics and the corresponding ion energy are generally known and are controlled by the frequency of the periodic waveforms and the associated phase interaction. Another approach in voltage, current, or power delivery systems involves dual frequency control. That is, two frequency sources operating at different frequencies are used to power a plasma chamber to provide substantially independent control of ion and electron densities. In various configurations, the frequency may be a RF frequency.

Another approach utilizes wideband RF power sources to drive a plasma chamber. A wideband approach presents certain challenges. One challenge is coupling the power to the electrode. A second challenge is that the transfer function of the generated waveform to the actual sheath voltage for a desired IEDF must be formulated for a wide process space to support material surface interaction. In one responsive approach in an inductively coupled plasma system, controlling power applied to a source electrode controls the plasma density while controlling power applied to the bias electrode modulates ions to control the IEDF to provide etch rate and etch feature profile control. By using source electrode and bias electrode control, the etch rate and other various etch characteristics are controlled via the ion density and energy.

As integrated circuit and device fabrication continues to evolve, so do the power requirements for controlling the process for fabrication. For example, with memory device fabrication, the requirements for bias voltage, current, or power continue to increase. Increased voltage, current, or power generates higher and more energetic ions for increased directionality or anisotropic etch feature profiles and faster surface interaction, thereby increasing the etch rate and allowing higher aspect ratio features to be etched. In one nonlimiting example, in some voltage, current, or power delivery systems, increased ion energy is sometimes accompanied by a lower bias frequency requirement along with an increase in the power and number of bias power sources coupled to the plasma sheath created in the plasma chamber. The increased power at a lower bias frequency and the increased number of bias power sources results in intermodulation distortion (IMD) from sheath modulation. The IMD emissions can significantly reduce power delivered by the source where plasma generation occurs. U.S. Pat. No. 10,821,542, issued Nov. 3, 2020, entitled Pulse Synchronization by Monitoring Power in Another Frequency Band, assigned to the assignee of the present application, and incorporated by reference herein, describes a method of pulse synchronization by monitoring power in another frequency band. In the referenced U.S. patent application, the pulsing of a second RF generator is controlled in accordance with detecting at the second RF generator the pulsing of a first RF generator, thereby synchronizing pulsing between the two RF generators.

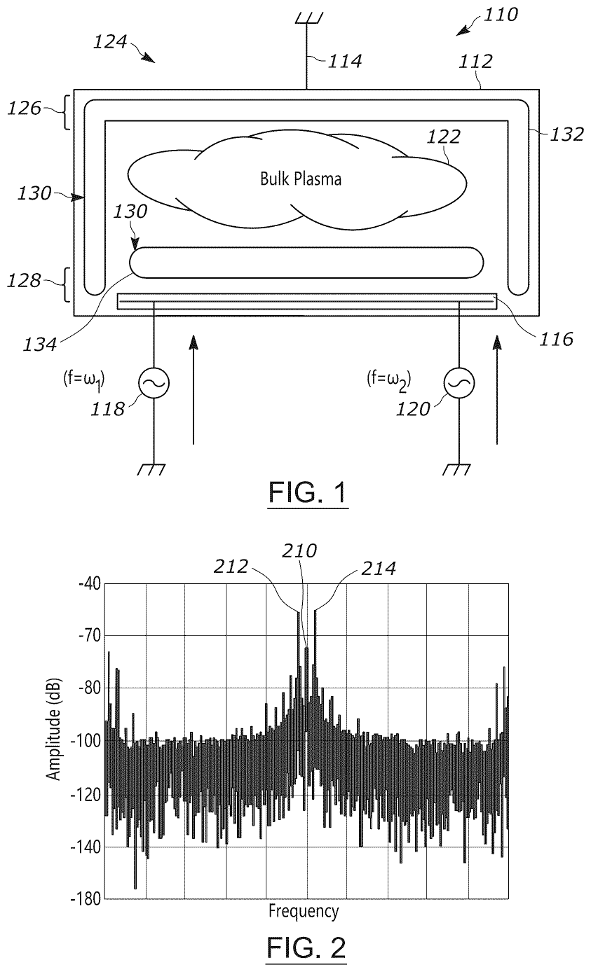

FIG. 1 depicts a cross-sectional view of a generalized representation of a dual voltage, current, or power input plasma system 110. Plasma system 110 includes first electrode 112, a wall of plasma chamber 124, connected to ground 114 and second electrode 116 spaced apart from first electrode 112. A voltage, current, or power supply; voltage, current, or power source; RF power generator; or RF power source 118, 120 (the terms may be used herein interchangeably to refer to an appropriately configured voltage, current, or power supply, source, or generator) applies power plasma chamber 124 via second electrode 116. A first power source 118 generates a first voltage, current, or power signal as described above, applied to second electrode 116 at a first frequency ƒ=ω₁. A second power source 120 generates a second DC (ω=0) or sinusoidal voltage, current, or power applied to second electrode 116.

In various configurations, first power source 118 operates at a frequency ƒ=ω₁, where ω₁=nω₂ that is the n^{th} harmonic frequency of the frequency of second power source 120. In various other configurations, first power source 118 and second power source 120 operate at frequencies that are not multiples. In various configurations, power sources 118, 120 are locked to operate at the same frequency, with fixed or varying relative phases. In various other configurations, power sources 118, 120 may operate at different frequencies, voltages, currents, or powers, and relative phases. In other various configurations, first power source 118 and second power source 120 may be synchronously or asynchronously pulsed to modulate an underlying carrier signal, where the respective pulse or pulsed waveforms may have one or a plurality of states and various sinusoidal, nonsinusoidal, and repeating, or nonrepeating shapes.

In various configurations power source 118 outputs a source waveform to ignite or generate plasma 122 or control the plasma density, and power source 120 outputs a bias waveform that modulates the ions to control the ion potential or ion energy of the plasma 122. In various configurations the source waveform or bias waveform may be a sinusoidal or continuous wave signal. In other various configurations, source waveform or bias waveform may be a pulsed sinusoidal, nonsinusoidal, or direct current (DC) signal, having one or more of a varying amplitude, frequency, or duty cycle, as will be described in great detail herein. Further, by way of nonlimiting example, the bias waveform may be a RF waveform, a pulsed RF waveform, a DC waveform, a pulsed DC waveform, a pulsed rectangular waveform, or a piecewise linear waveform. A piecewise linear waveform is described in U.S. Pat. No. 10,396,601, issued on Aug. 27, 2019, entitled Piecewise RF Power Systems and Methods for Supplying Pre-Distorted RF Bias Voltage Signals to an Electrode in a Processing Chamber, assigned to the assignee of the present application, and incorporated by reference herein. In various configurations, a radio frequency (RF) signal may be considered as having a frequency in the range of approximately 100 kHz to 2.5 GHz, but in some configurations can span 2 kHz to 300 GHz.

In various configurations, bias voltage, current, or power and source voltage, current, or power may be applied to the lower electrode, such as second electrode 116, in various combinations. In another nonlimiting example, one of bias voltage, current, or power and source voltage, current, or power may be applied to second electrode 116, and the other of bias voltage, current, or power and source voltage, current, or power may be applied to another electrode (not shown). In various configurations, power sources 118, 120 can be connected to the same electrode, while a counter electrode may be connected to ground 114, or to yet a third DC (ω=0), or other voltage, current, or sources having one or more of a varying amplitude, frequency, or duty cycle power generator (not shown), including, but not limited to, a RF signal. Further, in various configurations, voltage, current, or power may be coupled to plasma chamber 124 using an inductively coupled plasma (ICP) or a capacitively coupled plasma (CCP), as described above. Coordinated operation of respective power

sources 118, 120 results in generation and control of plasma 122. As shown in FIG. 1 in schematic view, plasma 122 is formed within an asymmetric sheath 130 of plasma chamber 124. Sheath 130 includes a ground or grounded sheath 132 and a powered sheath 134. A sheath is generally described as the surface area surrounding plasma 122. As can be seen in schematic view in FIG. 1, grounded sheath 132 has a relatively large surface area 126. Powered sheath 134 has a small surface area 128. Because each sheath 132, 134 functions as a dielectric between the conductive plasma 122 and respective electrodes 112, 116, each sheath 132, 134 forms a capacitance between plasma 122 and respective electrodes 112, 116.

As will be described in greater detail herein, in systems in which a high frequency voltage, current, or power source, such as first power source 118, and a low frequency voltage, current, or power source, such as first power source 120, intermodulation distortion (IMD) products are introduced. IMD products result from a change in plasma sheath thickness, thereby varying the capacitance between plasma 122 and first electrode 112, via grounded sheath 132, and plasma 122 and second electrode 116, via powered sheath 134. The variation in the capacitance of powered sheath 134 generates IMD. Variation in powered sheath 134 has a greater impact on the capacitance between plasma 122 and second electrode 116 and, therefore, on the reverse IMD emitted from plasma chamber 124. In some plasma systems, grounded sheath 132 acts as a short circuit and is not considered for its impact on reverse IMD.

FIG. 2 shows a plot of amplitude versus frequency for an exemplary voltage, current, or power delivery system having a high frequency source such as first power source 118, and a low frequency source, such as second power source 120. FIG. 2 shows amplitude of the reflected energy with respect to frequency for first power source 118. FIG. 2 includes a center peak 210 indicating the center frequency of operation of the high frequency power source, such as first power source 118 of FIG. 1. On either side of center peak 210, FIG. 2 also shows IMD components 212, 214 which represent the IMD introduced by the application of energy from a low frequency power source, such as second power source 120 of FIG. 1. By way of nonlimiting example, if high frequency or first power source 118 operates at a frequency of 60 MHz, and low frequency or second power source 120 operates at 400 kHz, IMD components can be found at 60 MHz +/−n*400 kHz, where n is any integer. Thus, peaks of IMD components 212, 214 represent the high frequency +/− the low frequency of the respective power supplies. Driving an electrode at multiple harmonics, such as shown in FIG. 1, provides the opportunity to control DC self-bias electrically and to tailor the energetic levels of ion density.

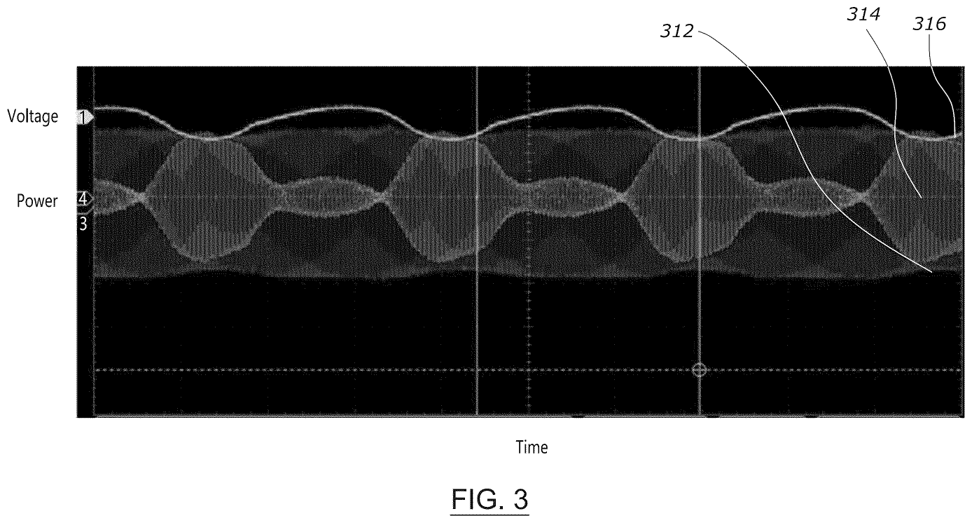

FIG. 3 shows waveforms of forward voltage 312 and reverse or reflected voltage 314 respectively to and from a higher frequency or source RF generator. By way of nonlimiting example, the source RF generator may operate at 60 MHz. FIG. 3 also shows a voltage waveform 316 indicating the output voltage of a lower frequency or bias RF generator, operating at, by way of nonlimiting example, 400 KHz. As can be seen in FIG. 3, reflected voltage 314 of the source RF generator varies in accordance with the voltage fluctuations of voltage waveform 316 of bias RF generator. As can also be seen in FIG. 3, when the reflected voltage 314 increases, the voltage delivered to the load or the reactor (the difference between the forward voltage 312 and the reflected voltage 314) decreases.

As can be seen from FIG. 3, fluctuation of voltage waveform 316 of the bias RF generator causes resultant IMD experienced at the load. The resultant IMD causes fluctuations in reverse voltage 314 that adversely affect delivery of forward voltage 312. By minimizing IMD, a more consistent forward voltage at a higher amplitude can be delivered to the load or process chamber. It should be understood that while the waveforms described in FIG. 3 are voltage waveforms, the principles described herein apply equally with respect to detecting power instead of voltage.

In multi-generator plasma control applications, IMD-related load variation effects such as those shown in FIG. 3 are a well-known issue. A number of prior approaches exist for addressing the challenges associated with IMD effects. In one nonlimiting example, a Disturbance Cancellation System (DCS) allows for compensation of load variation via adjustment of the frequency actuator on the higher frequency generator in sync with the period of the lower frequency generator. A seminal approach to disturbance cancellation can be found with respect to U.S. Pat. No. 9,947,514, issued on Apr. 17, 2018, entitled Plasma RF Bias Cancellation System, assigned to the assignee of the present application, and incorporated by reference herein. The RF bias cancellation concepts have been extended to other system actuators, such as a matching network reactance, as described in U.S. Pat. No. 11,158,488, issued on Oct. 26, 2021, entitled High Speed Synchronization Of Plasma Source/Bias Power Delivery, assigned to the assignee of the present application, and incorporated by reference herein. Further approaches can be found in connection with modulating the source power amplifier drive, which is described in U.S. Pat. No. 11,232,931, issued on Jan. 25, 2022, entitled Intermodulation Distortion Mitigation Using Electronic Variable Capacitor, assigned to the assignee of the present application, and incorporated by reference herein.

To take advantage of the DCS frequency offset or hopping approach described in the patents reference above in connection with DCS approach, a frequency actuator profile or hopping pattern must be tuned to effect disturbance cancellation. One approach to tuning the frequency actuator profile or hopping pattern is presented in U.S. Pat. No. 11,527,384, issued on May 26, 2022, entitled Apparatus And Tuning Method For Mitigating RF Load Impedance Variations Due To Periodic Disturbance, assigned to the assignee of the present application, and incorporated by reference herein. The approach uses iterative learning control (ILC) to learn the actuator profile or hopping pattern. Present ILC approaches focus on optimizing a cost metric across repetitive cycles of the bias period. A fundamental assumption of ILC is that the behavior for consecutive bias cycles should be generally consistent. Although individual pulse states can be addressed by effectively creating separate tuners for each state, no provision exists in the prior approaches for addressing within-state variability. That is within a pulse state, which will be described in great detail, different IMD patterns appear between the leading edge and the trailing edge of a pulse state.

Within pulse state variation of IMD effects is presently experimentally observed for existing methods for tuning the actuator profile or hopping pattern. In various approaches, there may be a limitation on the tuner relying on data collected at the leading edge of the pulse state or the trailing edge of the pulse state resulting from sample collection bandwidth limitations. Relying on data collected at either the leading edge of the pulse state or the trailing edge of the pulse state can provide improved stability and convergence. However, doing so can also lead to sub-optimal tuning across the pulse because optimal tuning is typically achieved in the portion of the state where data is collected.

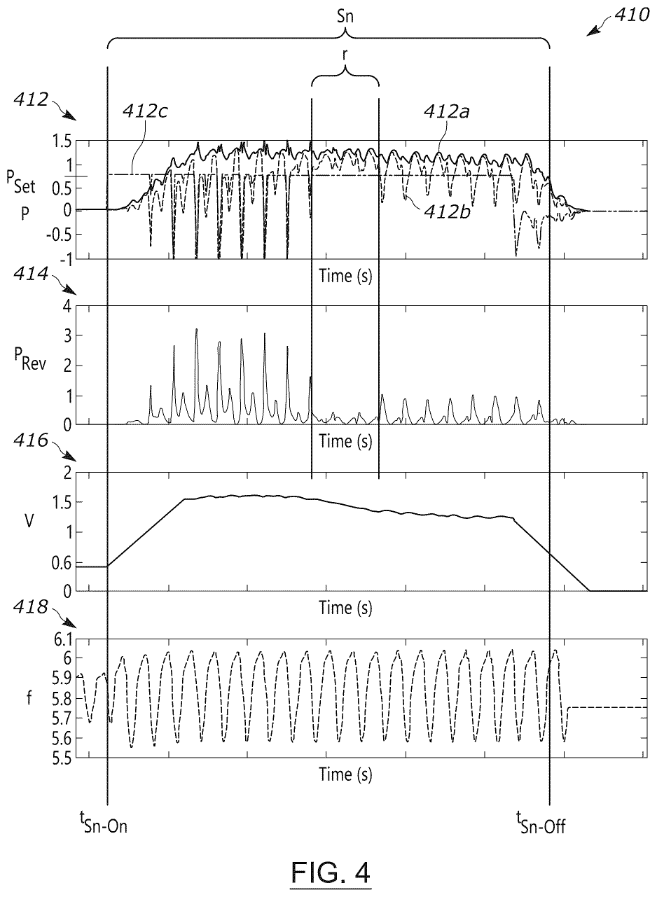

With reference to FIG. 4, FIG. 4 shows a plurality of waveforms 410, including forward power waveforms 412, reverse power waveform 414, drive signal waveform 416, and frequency offset or hopping pattern waveform 418. Waveforms 410 represent varying actuators and sensed electrical characteristics or parameters for the on-period of a single pulse state Sn. Drive signal waveform 416 represents a control voltage applied to a power amplifier input, such as of a source power generator to activate state Sn. Frequency offset or hopping pattern waveform 418 indicates a commanded frequency variation in the output frequency of the source power generator. By way of nonlimiting example, the source power generator outputs a center frequency of 58 MHz which may be varied between approximately 55 to 61 MHz in order to improve an impedance match between the source power generator and a load receiving the output from the source power generator.

In various configurations, forward power waveforms 412 include forward power 412a, delivered power 412b, and forward power limits 412c waveforms. Forward power waveform 412a indicates the power output of the source power generator. Delivered power waveform 412b indicates the power delivered to the load and represents the forward power as shown by forward power waveform 412a less the reverse power as indicated by reverse power waveform 414. In various configurations, the power output by source power generator is output at a setpoint Pset as shown in connection with waveforms 412. The delivered limit 412c indicates limits to the power output from source power generator and may be commanded in order to protect various system components.

In various configurations, disturbance cancellation is effected by determining frequency offset or hopping pattern waveform 418 and varying frequency offset or hopping pattern waveform 418 to correspondingly vary impedance match between the output of the source power generator and the load, thereby controlling delivered power 412b. In present disturbance cancellation systems, frequency offset or hopping pattern waveform 418 varies consistently in accordance with the output waveform from the bias power generator in order to compensate for IMD effects introduced by the output of the bias power generator. Thus, frequency offset or hopping pattern waveform 418 varies the impedance match between the source power generator and the load in order to compensate for IMD introduced by the bias power generator.

The frequency offset or hopping pattern defined by frequency waveform 418 is generated by measuring one or more predetermined parameters for pulse state Sn. The frequency offset or hopping pattern waveform 418 is generated in order to optimize the one or more predetermined parameters. In various configurations, the predetermined parameters may be used to generate a cost function, and the value of the cost function may be one of maximized or minimized in order to provide the desired delivered power. In various configurations, data may not be sampled over the entirety of pulse state Sn because of various system limitations.

As can be seen in FIG. 4, delivered power waveform 412b is optimal over a particular region r. In areas outside region r, delivered power is less than delivered power within region r and more variable. Further, reverse power waveform 414 is optimal for only a few cycles of the bias generator near the center of pulse state Sn, with the reverse power being much larger in proximity to both the leading edge (time t_{Sn-ON}) and trailing edge (time t_{Sn-OFF}). Further yet, in present disturbance cancellation systems, frequency offset or hopping pattern waveform 418 is generally consistent over the entirety of pulse state Sn in accordance with the bias waveform, though such consistency does not lead to consistent delivered power 412b. Thus, it is desirable to provide a disturbance cancellation system that provides frequency offset or hopping pattern waveform 418 that yields a more consistent power delivery of each pulse state.

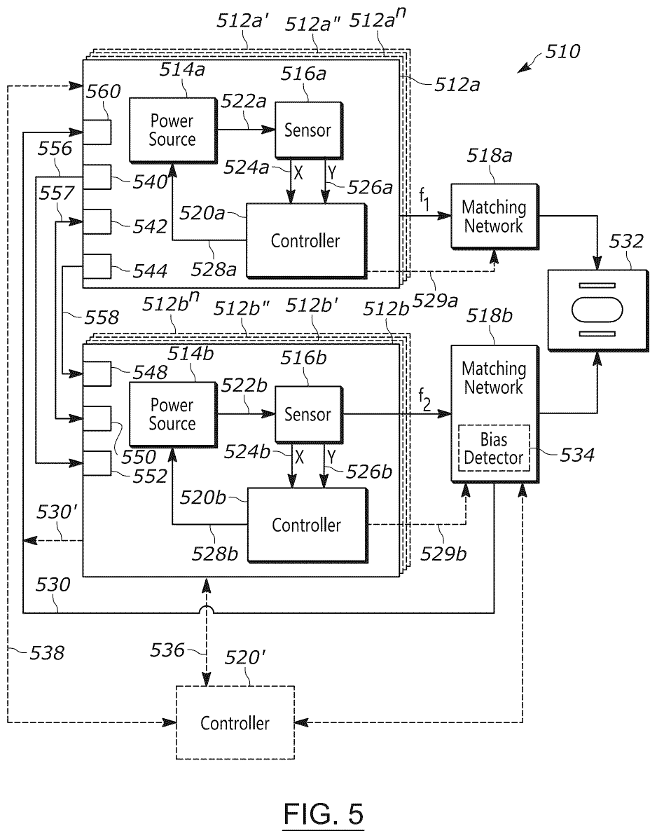

FIG. 5 depicts a RF generator or power supply system 510. Power supply system 510 includes a pair of radio frequency (RF) generators or power supplies 512a, 512b, matching networks 518a, 518b, and load 532, such as a nonlinear load, which may be a plasma chamber, plasma reactor, process chamber, and the like. In various configurations, generator 512a is referred to as a source generator or power supply, and matching network 518a is referred to as a source matching network. Further, in various configurations, one or both of voltage current, or power generators or power supplies 512a, 512b may output a continuous or pulsed time-varying voltage, current, or power signal or a continuous or pulsed DC voltage, current, or power signal. Also in various configurations, generator 512b is referred to as a bias generator or power supply, and matching network 518b is referred to as a bias matching network. It will be understood that components can be referenced individually or collectively using the reference number with or without a letter subscript or a prime symbol. In various configurations, one or both of matching networks 518a, 518b may be implemented as a RF blocking filter, rather than an impedance match, such as may be the case for a matching network receiving a pulsed DC or nonsinusoidal signal. In various other configurations, one or both of matching networks 518a, 518b may be omitted.

In various configurations, source generator 512a receives a control signal 530 from matching network 518b, generator 512b, or a control signal 530′ from bias generator 512b. Control signals 530 or 530′ represent an input signal to source generator 512a that indicates one or more operating characteristics or parameters of bias generator 512b. In various configurations, a synchronization bias detector 534 senses the signal output from matching network 518b to load 532 and outputs synchronization or trigger signal 530 to source generator 512a. In various configurations, synchronization or trigger signal 530′ may be output from bias generator 512b to source RF generator 512a, rather than trigger signal 530. A difference between trigger or synchronization signals 530, 530′ may result from the effect of matching network 518b, which can adjust the phase between the input signal to and output signal from matching network. Signals 530, 530′ include information about the operation of bias RF generator 512b that in various configurations enables predictive responsiveness to address periodic fluctuations in the impedance of plasma chamber or load 532 caused by the bias generator 512b. When control signals 530 or 530′ are absent, generators 512a, 512b operate autonomously.

Generators 512a, 512b include respective power sources or amplifiers 514a, 514b, sensors 516a, 516b, and processors, controllers, or control modules 520a, 520b. Power sources 514a, 514b generate respective voltage, current, or power signals 522a, 522b, various configurations of which are described above, output to respective sensors 516a, 516b. RF power signals 522a, 522b pass through sensors 516a, 516b and are provided to matching networks 518a, 518b as respective power signals ƒ₁ and ƒ₂. Sensors 516a, 516b output signals that vary in accordance with various parameters sensed from load 532. While sensors 516a, 516b, are shown within respective generators 512a, 512b, sensors 516a, 516b can be located externally to generators 512a, 512b. Such external sensing can occur at the output of the generator, at the input of an impedance matching device located between the generator and the load, or between the output of the impedance matching device (including within the impedance matching device) and the load.

Sensors 516a, 516b detect various operating parameters and output signals X and Y. Sensors 516a, 516b may include voltage, current, and/or directional coupler sensors. Sensors 516a, 516b may detect (i) voltage V and current I and/or (ii) forward power P_{FWD} output from respective power amplifiers 514a, 514b and/or RF generators 512a, 512b and reverse or reflected power P_{REV} received from respective matching networks 518a, 518b or load 532 connected to respective sensors 516a, 516b. The voltage V, current I, forward power P_{FWD}, and reverse power P_{REV} may be scaled, filtered, or scaled and filtered versions of the actual voltage, current, forward power, and reverse power associated with the respective power sources 514a, 514b. Sensors 516a, 516b may be analog or digital sensors or a combination thereof. In a digital implementation, the sensors 516a, 516b may include analog-to-digital (A/D) converters and signal sampling components with corresponding sampling rates. Signals X and Y can represent any of the voltage V and current I or forward (or source) power P_{FWD} reverse (or reflected) power P_{REV}.

Sensors 516a, 516b generate sensor signals X, Y, which are received by respective controllers or control modules 520a, 520b. Control modules 520a, 520b process the respective X, Y signals 524a, 526a and 524b, 526b and generate one or a plurality of feedforward or feedback control signals 528a, 528b to respective power sources 514a, 514b. Power sources 514a, 514b adjust voltage, current, or power signals 522a, 522b based on the received one or plurality feedback or feedforward control signal. In various configurations, control modules 520a, 520b may control matching networks 518a, 518b, respectively, via respective control signals 529a, 529b based on, for example, X, Y signals 524a, 526a and 524b, 526b. Control modules 520a, 520b may include one or more proportional-integral (PI), proportional-integral-derivative (PID), linear-quadratic-regulator (LQR) controllers or subsets thereof and/or direct digital synthesis (DDS) component(s) and/or any of the various components described below in connection with the modules.

In various configurations, control modules 520a, 520b may include functions, processes, processors, or submodules. Control signals 528a, 528b may be control or actuator drive signals and may communicate DC offset or rail voltage, voltage or current magnitude, frequency, and phase components, and the like. In various configurations, feedback control signals 528a, 528b can be used as inputs to one or multiple control loops. In various configurations, the multiple control loops can include a proportional-integral (PI), proportional-integral-derivative (PID) controllers, linear-quadratic-regulator (LQR) control loops, or subsets thereof, for RF drive, and for power supply rail voltage. In various configurations, control signals 528a, 528b can be used in one or both of a single-input-single-output (SISO) or multiple-input-multiple-output (MIMO) control scheme. An example of a MIMO control scheme can be found with reference to U.S. Pat. No. 10,546,724, issued on Jan. 28, 2020, entitled Pulsed Bidirectional Radio Frequency Source/Load, assigned to the assignee of the present application, and incorporated by reference herein. In other configurations, signals 528a, 528b can provide feedforward control as described in U.S. Pat. No. 10,049,857, issued Aug. 14, 2018, entitled Adaptive Periodic Waveform Controller, assigned to the assignee of the present application, and incorporated by reference herein.

In various configurations, power supply system 510 can include controller 520′. Controller 520′ may be disposed externally to either or both of generators 512a, 512b and may be referred to as external or common controller 520′. In various configurations, controller 520′ may implement one or a plurality of functions, processes, or algorithms described herein with respect to one or both of controllers 520a, 520b. Accordingly, controller 520′ communicates with respective generators 512a, 512b via a pair of respective links 536, 538 which enable exchange of data and control signals, as appropriate, between controller 520′ and generators 512a, 512b. For the various configurations, controllers 520a, 520b, 520′ can distributively and cooperatively provide analysis and control of generators 512a, 512b. In various other configurations, controller 520′can provide control of generators 512a, 512b, eliminating the need for the respective local controllers 520a, 520b.

In various configurations, power source 514a, sensor 516a, controller 520a, and matching network 518a can be referred to as source RF power source 514a, source sensor 516a, source controller 520a, and source matching network 518a, respectively. Similarly in various configurations, RF power source 514b, sensor 516b, controller 520b, and matching network 518b can be referred to as bias power source 514b, bias sensor 516b, bias controller 520b, and bias matching network 518b, respectively. In various configurations and as described above, the source term refers to the generator or voltage, current, or power source that generates a plasma, and the bias term refers to the generator or voltage, current, or power source that tunes ion potential and the Ion Energy Distribution Function (IEDF) of the plasma. In various configurations, the source and bias power supplies operate at different frequencies or duty cycles. In various configurations, the source power supply operates at a higher frequency or duty cycle than the bias power supply. In various other configurations, the source and bias power supplies operate at the same frequencies or duty cycles or substantially the same frequencies or duty cycles.

According to various configurations, in addition to or by way of partial or total substitution to the synchronization signals described above with respect to signals 530, 530′, source generator 512a and bias generator 512b include multiple ports to communicate with each other and with external devices. Source generator 512a includes pulse synchronization port 540, communication port 542, RF port 544, and control signal port 560. Bias generator 512b includes RF port 548, digital communication port 550, and pulse synchronization port 552. Pulse synchronization port 540 of source generator 512a communicates pulse synchronization signals via link 556 with pulse synchronization port 552 of bias generator 512b. Communication port 542 of source generator 512a and communication port 550 of bias generator 512b communicate data and information via a communication link 557. RF port 544 of source generator 512a communicates with RF port 548 via communication link 558. Control signal port 560 of source generator 512a receives one or both of control signals 530, 530', as described above. In various configurations, one or more of the ports described above may communicate with matching network 518 for communicating sensed or control signals, as may be described herein.

In various configurations, communication between pulse synchronization port 540 and pulse synchronization port 552 may be unidirectional or bidirectional between source generator 512a and bias generator 512b. In various configurations, one of source generator 512a and bias generator 512b communicate, by way of nonlimiting example, envelope pulse information to the other of bias generator 512b and source generator 512a. In various configurations, one or multiple communication links 556 link pulse synchronization port 540 and pulse synchronization port 552. In various configurations, communication between pulse synchronization port 540 and pulse synchronization port 552 may occur via analog or digital communication.

In various configurations, communication between communication port 542 of source generator 512a and communication port 550 of bias generator 512b may be unidirectional or bidirectional between source generator 512a and bias generator 512b. In various configurations, communication port 542 of source generator 512a and communication port 550 of bias generator 512b communicate, by way of nonlimiting example, data, information, or synchronization signals. In various configurations, one or multiple communication links 557 link pulse synchronization port 542 and pulse synchronization port 550 In various configurations, communication between pulse synchronization port 542 and pulse synchronization port 550 may occur via analog or digital communication.

In various configurations, communication between RF port 544 of source generator 512a and RF port 548 of bias generator 512b may be unidirectional or bidirectional between source generator 512a and bias generator 512b. In various configurations, RF port 544 of source generator 512b and RF port 548 of bias generator 512b communicate, by way of nonlimiting example, a signal indicating one or more of voltage, current, or power output by the respective generator. By way of nonlimiting example, time-varying RF signals, such as sinusoidal voltage, current, or power signals may be communicated. In various configurations, one or multiple communication links 558 link signal port 544 and signal port 548. In various configurations, communication between signal port 544 and signal port 548 may occur via analog or digital communication.

In various configurations, a control signal communicated via communications link 558 is substantially the same as the control signal controlling source generator 512a. In various other configurations, the control signal communicated via communications link 558 is the same as the control signal controlling source generator 512a, but is phase shifted within source generator 512a in accordance with a requested phase shift generated by bias generator 512b. Thus, in various configurations, source generator 512a and bias generator 512b are driven by substantially identical control signals or by substantially identical control signals phase shifted by a predetermined amount.

In various configurations, power supply system 510 may include multiple source generators 512a and multiple bias generators 512b. By way of nonlimiting example, a plurality of source generators 512a, 512a′, 512a″, . . . , 512aⁿ can be arranged to provide a plurality of output power signals to one or more source electrodes of load 532. Similarly, a plurality of bias generators 512b, 512b′, 512b″, . . . , 512bⁿ may provide a plurality of output power signals to a plurality of bias electrodes of load 532. When source generator 512a and bias generator 512b are configured to include a plurality of respective source generators or bias generators, each generator will output a separate signal to a corresponding plurality of matching networks 518a, 518b, configured to operate as described above, in a one-to-one correspondence. In various other configurations, there may not be a one-to-one correspondence between each generator and matching network. In various configurations, multiple source electrodes may refer to multiple electrodes that cooperate to define a composite source electrode. Similarly, multiple bias electrodes may refer to multiple connections to multiple electrodes that cooperate to define a composite bias electrode.

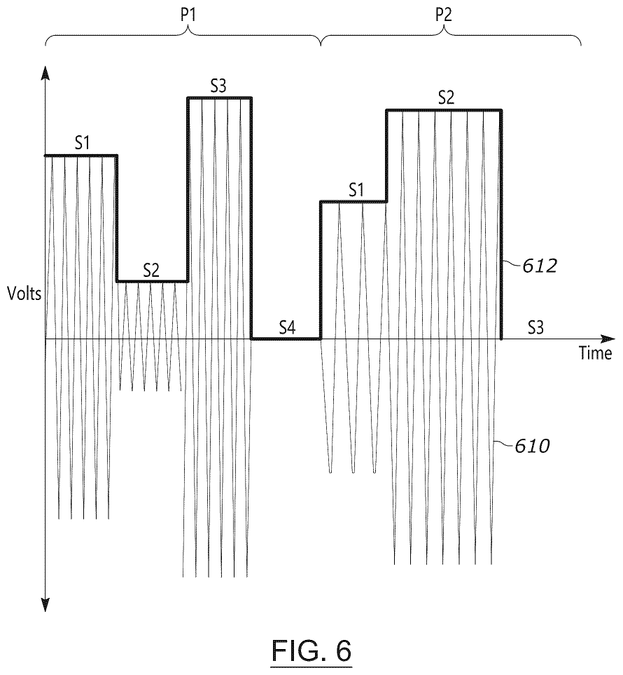

FIG. 6 shows a plot of voltage versus time to describe a pulse or pulsed mode of operation for delivering voltage, current, or power to a load, such as load 532 of FIG. 5. More particularly, FIG. 6 depicts signal or waveform 610, which, by way of nonlimiting example, is depicted as a sinusoidal signal or waveform. Waveform 610 may be referred to as a carrier waveform or carrier signal. Two multistate pulses P1, P2 of an envelope or pulse signal 612 having respective states S1-S4 and S1-S3 modulate waveform 610. As shown at states S1-S3 of P1 and S1-S2 of P2, when the pulses are ON, RF generator 512 outputs a signal as waveform 610 having an amplitude defined by the pulse magnitude of each state. Conversely, during states S4 of P1 and S3 of P2, the pulses are OFF, and generator 512 does not output waveform 610. Pulses P1, P2 can repeat at a constant duty cycle or a variable duty cycle, and states S1-S4, S1-S3 of each respective pulse P1, P2 may have the same or varying amplitudes and widths.

In various configurations, signal or waveform 610 may include, in various nonlimiting examples, a sinusoidal signal, nonsinusoidal waveform, square wave signal, rectangular wave signal, triangular signal, gaussian signal, or piecewise linear signal. In various other configurations, the waveform may have a complex shape including a narrow pulse voltage peak followed by a ramp down in the voltage. In various other configurations, signal or waveform 610 may have an arbitrary shape variable from cycle to cycle. In other various configurations, signal or waveform 610 may be periodic or nonperiodic. Further, the frequency of waveform 610 may vary between or within states S1-S4, S1-S3 and between or within pulses P1, P2. Further, the frequency of waveform may vary between or within states S1-S4, S1-S3 and between or within pulses P1, P2.

In various embodiments, pulse signal 612 may be embodied as a square wave or rectangular wave as shown in FIG. 6. By way of nonlimiting example, pulse signal 612 may be trapezoidal, triangular, or gaussian in shape. Further yet, pulse signal 612 may include pulses P1, P2 that include multiple states S1, ..., Sn of varying amplitude, duration, and shape. States S1, . . . , Sn may repeat within a fixed or variable period.

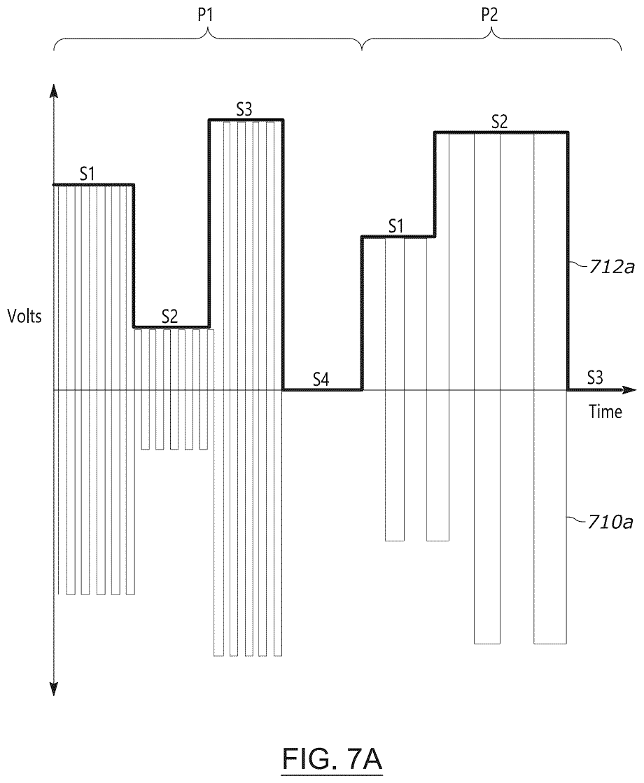

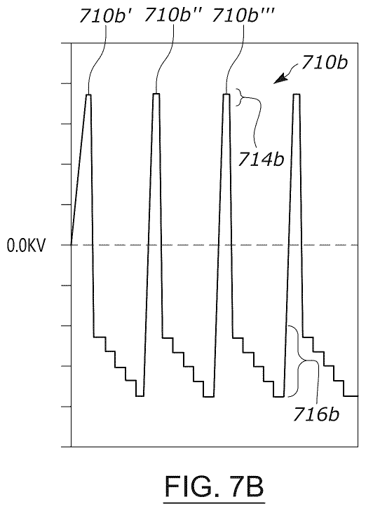

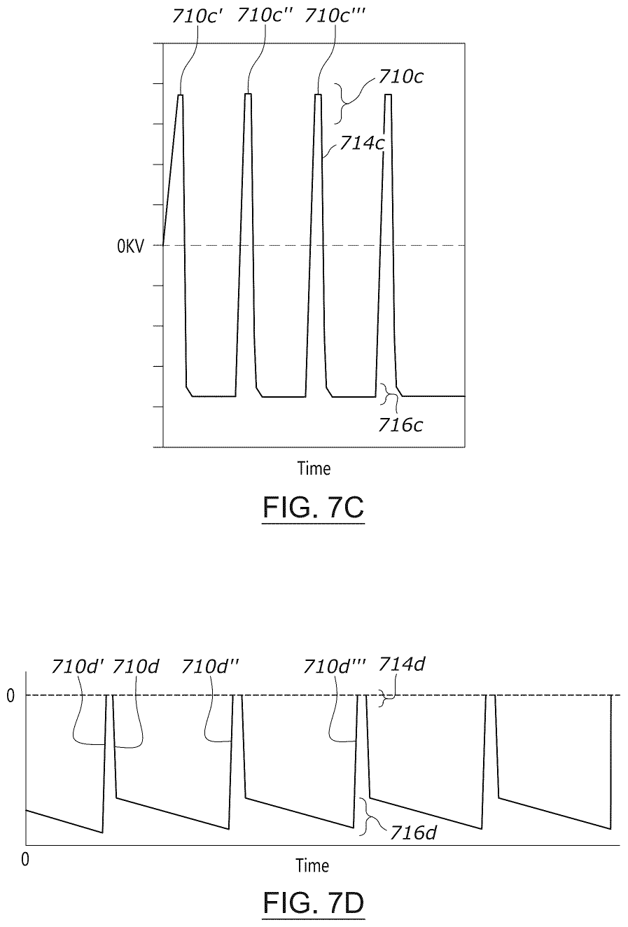

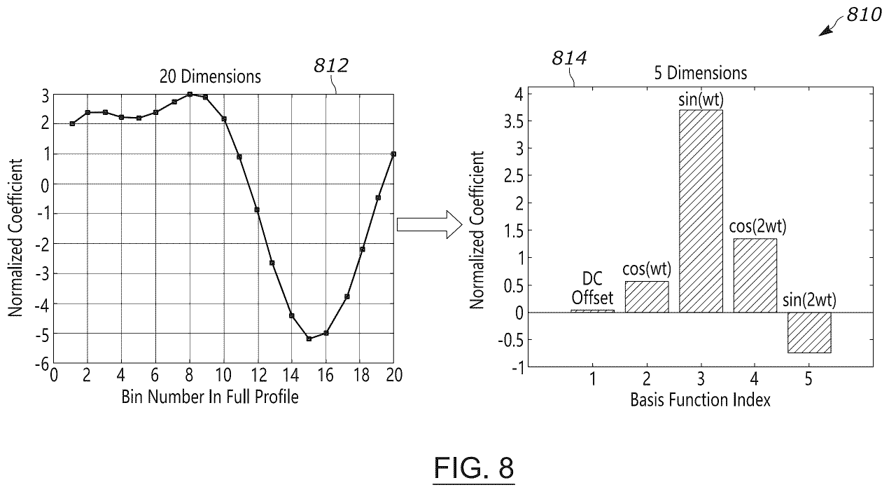

FIG. 7A depicts a plot of voltage versus time to describe an alternative pulse or pulsed mode of operation for delivering voltage, current, or power to a load, such as load 532 of FIG. 5. FIG. 7A depicts signal or waveform 710a, which, by way of nonlimiting example, is depicted as a square wave signal or waveform. Waveform 710a may be referred to as a pulsed DC signal or waveform or a DC carrier signal or waveform. Two multistate pulses P1, P2 of an envelope or pulse signal 712a having respective states S1-S4 and S1-S3 modulate waveform 710a. Waveform 710a is shown as a non-sinusoidal, periodic signal or waveform modulated by pulses P1 and P2. Waveform 710a may be a signal that pulses or oscillates between a first amplitude and a second amplitude over one or more cycles with various transitions therebetween.

At least one of the first and second amplitudes may vary over time in accordance with envelope or pulse signal 712a. As shown at states S1-S3 of P1 and S1-S2 of P2, when the pulses are ON, RF generator 512 outputs waveform 710a having an amplitude defined by the pulse magnitude of each state. Conversely, during states S4 of P1 and S3 of P2, the pulses are OFF, and generator 512 does not output waveform 710a. Thus, modulating signal or waveform 710a (pulsed DC signal or waveform) with envelope or pulse signal 712a provides a pulse-within-a-pulse effect. Pulses P1, P2 can repeat at a constant duty cycle or a variable duty cycle, and states S1-S4, S1-S3 of each respective pulse P1, P2 may have the same or varying amplitudes and widths. In various configurations, while waveform 710a of FIG. 7A is shown as a square wave, waveform 710a need not be implemented as a conventional square wave. The first and second amplitudes of waveform 710a may be flat, sloping, or peaked, and the transitions between the first and second amplitudes may include linear slopes, stairsteps, other shapes, or combinations thereof. Further, states S1-S4, S1-S3 and pulses P1, P2 may have the shapes, frequencies, duty cycles, and repetition rates as described above with respect to FIG. 6.

FIG. 7B shows one nonlimiting example of a pulsed DC carrier signal 710b having cycles 710b′, 710b″, 710b′″. Pulsed DC signal 710b includes high amplitudes 714b of cycles 710b′, 710b″, 710b′″ and low amplitudes 716b of cycles 710b′, 710b″, 710b′″. As shown in FIG. 7B, high amplitudes 714b are generally flat. Low amplitudes 716b have a stairstep transition, which may result from selected power amplifiers transitioning negatively or low sequentially. In various configurations, the stairstep transition of low amplitudes 716b provides improved slope compensation.

FIG. 7C shows one nonlimiting example of a pulsed DC carrier signal 710c having cycles 710c′, 710c″, 710c′″. Pulsed DC signal 710c includes high amplitude 714c of cycles 710c′, 710c″, 710c′″ and low amplitudes 716c of cycles 710c′, 710c″, 710c′″. As shown in FIG. 7C, high amplitudes 714c are generally flat. Low amplitudes 716c have a rounded shape at the transition from descending to generally constant, which may result from selected power amplifiers transitioning negatively or low sequentially with limited delay between each power amplifier transition. In various configurations, the pattern of low amplitudes 716c may improve ringing and overshoot.

FIG. 7D shows one nonlimiting example of a pulsed DC carrier signal 710d having cycles 710d′, 710d″, 710d′″. Pulsed DC signal 710d includes high amplitudes 714d of cycles 710d′, 710d″, 710d′″ and low amplitudes 716 d of cycles 710d′, 710d″, 710d′″. As shown in FIG. 7D, high amplitudes 714d are generally constant. Low amplitudes 716d include a linear transition which results from piecewise linear control of DC carrier signal 710d. By way of nonlimiting example, in various configurations, DC carrier signal 710d may be a piecewise linear waveform as described in U.S. Pat. No.10,396,601.

In various configurations, the pulsed DC carrier signal of FIGS. 7A-7E may represent the output of a power source, such as a source power source or bias power source. In other various configurations, the pulsed DC carrier signal of FIGS. 7A-7E may represent the output of a matching network prior to application to a load. It should be recognized that the various pulsed DC carrier signals of FIGS. 7A-7D may represent a shape of an output signal from a power source or a matching network.

In various configurations, pulse signal 612, 712 may be other than a square wave as shown in FIGS. 6, 7. Further, by way of nonlimiting example, envelope or pulse signal 612, 712 may be a single or multistate rectangular, trapezoidal, triangular, sawtooth, gaussian, or other shape that defines an envelope or modulating envelope of the underlying, modulated waveform 610. In various configurations, waveform 610, 710 may be referred to as a carrier signal and may occur or reoccur within fixed or variable periods or time periods. In various other configurations, waveform 610, 710 may vary in shape between each occurrence. Waveform 610, 710 may operate at frequencies that vary between states or within a state. In various other configurations, pulse signal 612, 712 may occur or reoccur within fixed or variable time periods and vary in shape between each occurrence. Further yet, pulses P1, P2 can have multiple states S1, . . . , Sn of varying amplitude, duration, and shape. States S1, . . . , Sn may repeat within fixed or variable periods and may include all or a portion of the various shapes described above.

According to the present disclosure, in addition to a primary set of basis functions, a secondary set of basis functions further tunes a control actuator within a given pulse state. An iterative learning control (ILC) approach can be used to learn and tune the primary or low-level function basis scalings. The primary or low-level basis function can be further varied across a pulse state in accordance with the secondary or high-level basis function. An ILC approach is implemented at a secondary level to further tune the within-pulse state basis scalings to further improve the cost metric.

One nonlimiting example of a secondary layer adjustment would be a linear ramp of a selected parameter or actuator for the low-level tuner across a given pulse state. This would enable the magnitude of the selected low-level parameter or actuator to linearly increase/decrease from the lead-edge to the trail-edge of the pulse state. An example of this is shown below for the case of a primary or low-level tuning using a Fourier basis and a linear ramp at the secondary or high-level tuning layer. In various configurations, secondary layer adjustments of the low-level basis parameters can take many forms. In the linear ramp adjustment described herein, the low-level basis coefficients may be adjusted in a linear approach from the start to the end of the pulse state.

FIG. 8 shows a relationship in which a pulse state is divided across its length in bins or time segments. In the disturbance cancellation system, a normalized coefficient or weight can be defined for each bin, which defines the offset profile for a given state. The bins in the full profile and normalized coefficients can be redefined using a set of basis functions with each index in the set of basis functions having a corresponding normalized coefficient. FIG. 8 shows a relationship 810 between the normalized coefficients in the full profile and the normalized coefficients for each basis function index. The relationship provides for a many-to-fewer correspondence between each bin and a basis function index. That is, the number of basis function indexes is less than the number of bins.

Waveform or plot 812 indicates a nonlimiting example of a frequency offset or hopping pattern waveform to effect disturbance cancellation. Waveform or plot 814 indicates a representation of waveform or plot 812 reduced from 20 dimensions to, by way of nonlimiting example, 5 dimensions. Waveform or plot 814 represents a normalized magnitude of a Fast Fourier Transform (FFT) of waveform or plot 812. As can be seen, waveform or plot 812 shows a relationship between 20 bins in full profile and normalized coefficients corresponding to each of the 20 bins in full profile. Plot 814, on the other hand, shows a relationship between a set of basis functions having 5 dimensions or indexes and normalized coefficients corresponding to each of the 5 dimensions. As can also be seen in plot 814, the basis function indexes or dimensions 1-5 correspond to DC offset, cos(ωt), sin(ωt), cos(2ωt), cos(2ωt), respectively. It will be understood that more or fewer dimensions or indexes can be determined using the FFT. Here, ω is the radian frequency of the synchronization signal and t represents time over one period of the synchronization signal. In various configurations, t is sampled to correspond to an associated bin number of waveform or plot 812.

As described above, the five basis function dimensions or indexes each define a basis vector or basis function—DC offset, cos(ωt), sin(ωt), cos(2ωt), and sin(2ωt). In various configurations, more dimensions can be used to improve precision, which can impact efficiency, and fewer dimensions can be used to improve efficiency, which can impact precision. The basis vectors or basis functions can be described generally as having (1+2n) dimensions, including DC offset, cos(ωt), sin(ωt), cos(2ωt), sin(2ωt), . . . , cos(nωt), and sin(nωt). In various configurations, the DC offset dimension may be omitted. In various other configurations, the DC offset dimension may be determined using a separate process, such as in a conventional frequency tuning loop. Further, as shown in waveform or plot 814, each dimension, basis vector, or basis function is scaled or weighted by a normalized coefficient in accordance with the FFT. Further yet, as can be seen in FIG. 8, waveform or plot 814 includes five basis function dimensions or indexes, and one or a plurality of the basis function indexes may be scaled, and each basis function may be scaled in one or more of the variations described according to the present disclosure.

FIG. 8 describes a conventional disturbance cancellation system and operates as limited as described above with respect to FIGS. 3 and 4. In a conventional disturbance cancellation system as described above, the normalized coefficient for each basis function index is predetermined and remains fixed for the entirety of a particular pulse state. According to the present disclosure, the frequency actuator profile within a given pulse state may be tuned, or further tuned, using a secondary or high-level set of basis functions.

In one nonlimiting example, an iterative learning control approach can be used to learn the primary or low-level set of basis indexes or scalings. These scalings no longer need to remain constant across a pulse state, as they can be adjusted by a secondary or high-level set of basis indexes or scalings. An ILC approach is further implemented at a secondary or high-level to tune the pulse state basis scalings within the pulse, such as Sn, to further improve the cost metric as described above. One nonlimiting example of a secondary layer or high-level adjustment of a primary layer or low-level basis scaling would be a linear ramp of a given parameter for the primary layer or low-level tuner across a given pulse state. This would enable the magnitude of the primary layer or low-level parameter to linearly increase or decrease from the leading edge of the pulse state to the trailing edge of the pulse state.

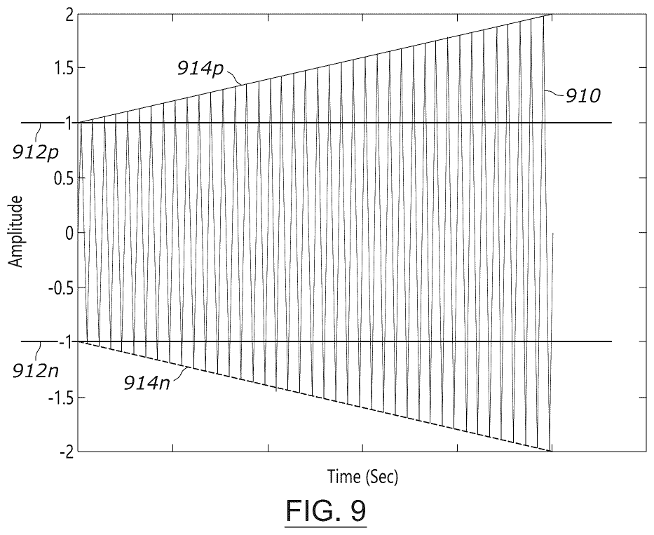

FIG. 9 shows one nonlimiting example of a secondary layer or high-level basis function scaling using a ramp function. FIG. 8 shows a basis function index and normalized coefficients for one example of a Fourier basis set being used to define the frequency offset or hopping pattern for a particular state. FIG. 9 shows the frequency offset or hopping pattern waveform 910 for the width of the particular pulse state defined by the amplitude of the fundamental Fourier component (sin(ω) or basis function index 3) of waveform or plot 914. In a conventional configuration, frequency offset or hopping pattern waveform 910 would have constant peaks at an amplitude of unity or one, including a positive peak 912p and negative peak 912n. According to the present disclosure, waveform 910 may be linearly scaled by a factor of two by a ramp function so that the peaks increase over the on period of the state. As shown in FIG. 9, positive peaks are scaled by a linear ramp 914p, and negative peaks are scaled by a linear ramp 914n.

The width of the pulse state is shown in FIG. 9, and the amplitude of the fundamental Fourier component increases linearly by a factor of two across the pulse state. In various configurations, linear ramp 914p and linear ramp 914n may be symmetric about a horizontal axis. In other various configurations, the scaling defined by linear ramps may be increasing or decreasing and need not be symmetric about a horizontal axis, or may only scale positive or negative components of the frequency offset or hopping pattern waveform 910. In other various configurations, the scaling may be exponentially increasing or decreasing and need not be symmetric about a horizontal axis, or may only scale positive or negative components of the frequency offset or hopping pattern waveform 910. In various configurations, the basis functions could be exponential of Fourier coefficients. In other configurations, a data-driven approach can be employed in which the required basis functions are derived from data using principal component analysis (PCA) of hopping pattern waveforms or solutions in higher dimensional spaces.

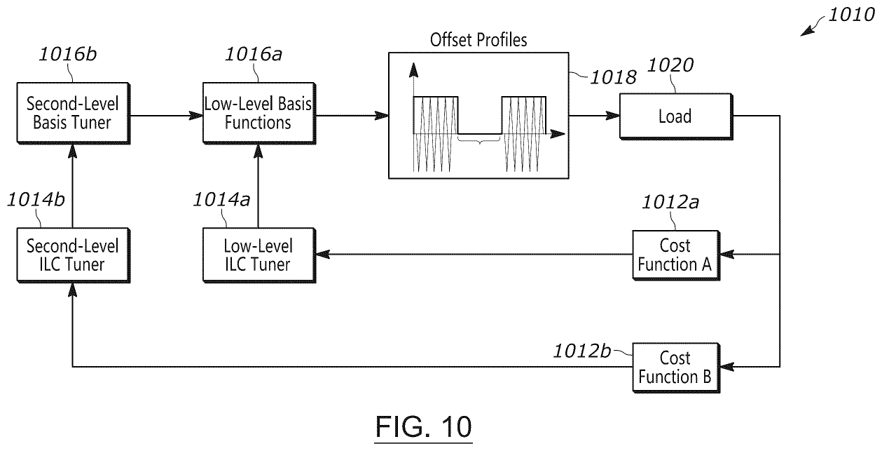

FIG. 10 is a schematic block diagram of a controller for a power delivery system applying two layers of basis functions for determining a frequency offset or hopping pattern. A plasma is generated in load 1020. Electrical parameter or characteristic data is generated based on electrical parameters or characteristics associated with load 1020 via sensors as described above and input to cost function module A 1012a and cost function module B 1012b. Cost function module A 1012a and cost function module B 1012b determine respective cost functions in accordance with electrical parameter or characteristic data. Cost function module A 1012a outputs a cost function value to primary or low-level ILC tuner module 1014a. Primary or low-level ILC tuner module 1014a uses an ILC approach to generate a frequency offset or hopping pattern waveform, such as plot 812 of FIG. 8. The output from primary or low-level ILC tuner module 1014a is input to low-level ILC basis function generation module 1016a, which generates basis functions, such as basis functions of plot 814 of FIG. 8.

Cost function module B 1012b outputs a cost function value to secondary or high-level ILC tuner module 1014b. Secondary or high-level ILC tuner module 1014b uses an ILC approach to generate a further adjustment to the frequency offset or hopping pattern output by primary or low-level ILC tuner module 1014a, such as values to scale the frequency offset or hopping pattern waveform output by primary or low-level ILC tuner module 1014a, such as ramps 914p, 914n of FIG. 9 in one nonlimiting example. The output from secondary or high-level ILC tuner module 1014b is input to high-level ILC basis function generation module 1016b, which generates secondary or high-level basis functions to adjust the basis functions output by low-level ILC basis function generation module 1016a. The output from low-level ILC basis function generation module 1016a is an offset profile 1018 which is used to control one of voltage, current, or power output by a power generator providing an input signal to load 1020.

In various configurations of FIG. 10, cost function A and cost function B may be the same or different to effect different tunings for a respective primary or low-level adjustment and secondary or high-level level adjustment. By way of nonlimiting example, primary or low-level cost function A may be directed to controlling average reflected power across pulse state Sn, while secondary or high-level cost function B may be directed to controlling the worst-case reflected power across pulse state Sn. In various configurations, the low-level basis dimensions may be first tuned using conventional approaches, such as tuning on a limited window of data or optimizing on average performance across the pulse state, as described with respect to FIG. 4. After this initial approach achieves acceptable convergence (either in terms of cost metric falling below a threshold or actuator updates becoming sufficiently small), the secondary or high-level tuning layer then fine-tunes the within-state frequency actuator profile. By way of nonlimiting example, a present tuner uses a set of Fourier basis functions to tune the shape of the required frequency offset or hopping pattern profile. Once this tuning has acceptably converged, a secondary tuner could allow the initial learned primary or low-level scale factors associated with the Fourier basis dimensions to vary across the pulse state, such as by linearly ramping as shown in FIG. 9.

Using the above-described sequential tuning provides flexibility to achieve acceptable performance in minimal time using existing methods, and further offers higher fidelity tuning subsequently as necessary. In some configurations, the initial tuning of the primary or low-level parameters could occur during an offline phase or during a limited portion of a customer plasma processing recipe. The secondary layer or high-level tuning then applies adjustments as plasma fabrication recipe steps occur.

In various configurations, primary or low-level basis functions may be defined, such as with a Fourier basis set, up to the third harmonic, with ILC adjustments occurring at the secondary or high-level layer. In such an approach, the parameters of the secondary layer or high-level basis functions could in an initial condition to mimic that of existing approaches. By way of nonlimiting example, for an initial condition with a linear ramp, a DC offset, and an initial slope value of zero, the secondary or high-level tuner then learns the variation within the pulse state Sn needed to improve beyond the performance of the initial, starting condition.

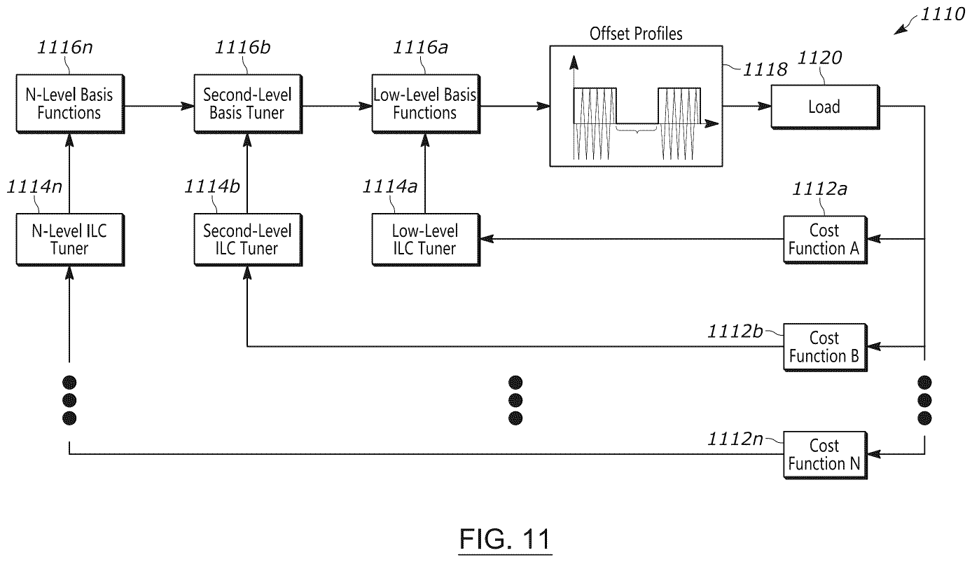

With reference to FIG. 11, in various other configurations, some etch recipes contain ramps or iterative steps that contain step changes in gas composition, chamber pressure, power setpoint, or other variation. These cycles may have a longer period compared to the pulsing described above, such as 100 ms to 10's of seconds. These cycle variations could be addressed with a tertiary level tuner, as shown in FIG. 11. FIG. 11 shows a N-ary tuning configuration in which up to N layers of tuning are available.

In FIG. 11, electrical parameter or characteristic data is generated based on electrical parameters or characteristics associated with load 1120 via sensors as described above is also input to cost function module N 1112n. Cost function module N 1112n outputs a cost function value to N^{th}-ary higher-level ILC tuner module 1114n. N^{th}-ary higher-level ILC tuner module 1114n uses an ILC approach to generate a further adjustment to the frequency offset or hopping pattern waveform output by low-level ILC tuner 1114a and high-level ILC tuner 1114b, such as values to scale the frequency offset or hopping pattern waveform output by low-level ILC tuner 1114a and high-level ILC tuner 1114b. The output from Nth-ary higher-level ILC tuner module 1114n is input to Nth-ary ILC basis function generation module 1116n, which generates higher-level or Nth-ary basis function dimensions or indexes to adjust the basis functions output by low-level ILC basis function generation module 1116a and high-level ILC basis function generation module 1116b. The output from low-level ILC basis function generation module 1116a is an offset profile 1118 which is used to control one of voltage, current, or power output by a power generator providing an input signal to load 1120. In various configurations, low-level basis components output from low-level ILC basis function generation module 1116a may be scaled, multiplied, or mixed in accordance with the output of high-level ILC basis function generation module 1116b. In other various configurations, adjustments output from high-level ILC basis function generation module 1116b may be added or combined, rather than scaled, multiplied, or mixed with the output of low-level ILC basis function generation module 1116a.

As can be seen from the various configurations described above, the present disclosure allows for various combinations of adjustment of the primary or low-level function basis scaling. In one configuration, the N-ary or high-level function basis scaling may further adjust the primary or low-level function basis scaling for each state Sn of a pulse, though not every state of a pulse is necessarily adjusted by the N-ary or high-level function basis scaling. That is only selected states of a pulse need be tuned using both the primary and secondary function basis scalings. In other configurations, the primary or low-level function basis scaling may be adjusted by the one or more of the N-ary or high-level function basis scaling over a plurality of states Sn, though each state Sn in which adjustment occurs need not be adjacent (nonadjacent) to other, adjusted states Sn. Further, selected states may be adjusted by one or more of the N-ary or high-level function basis scalings, while other states Sn may not be adjusted by any of the N-ary or high-level function basis scalings.

In various configurations, the electrical characteristics or parameters sensed or determined can include, but are not limited to reverse or reflected power P_{REV}, delivered power, delivered power error, a reflection coefficient (Γ), or the square of the magnitude of a reflection coefficient (|Γ|²) . Further yet, other parameters may be considered in connection with the disturbance cancellation system described herein include a plasma fabrication recipe steps and mechanical devices controlled in connection with plasma fabrication. One or plurality of the electrical or mechanical characteristics or parameters can be considered individually or as a plurality for control or may be inputs individually or as a plurality to cost functions that are maximized or minimized in connection with disturbance cancellation. Further, in addition to controlling frequency, one or plurality of system actuators can be controlled to affect disturbance cancellation, including drive voltage applied to the power amplifier, and matching network controls for both mechanical and electrical matching networks.

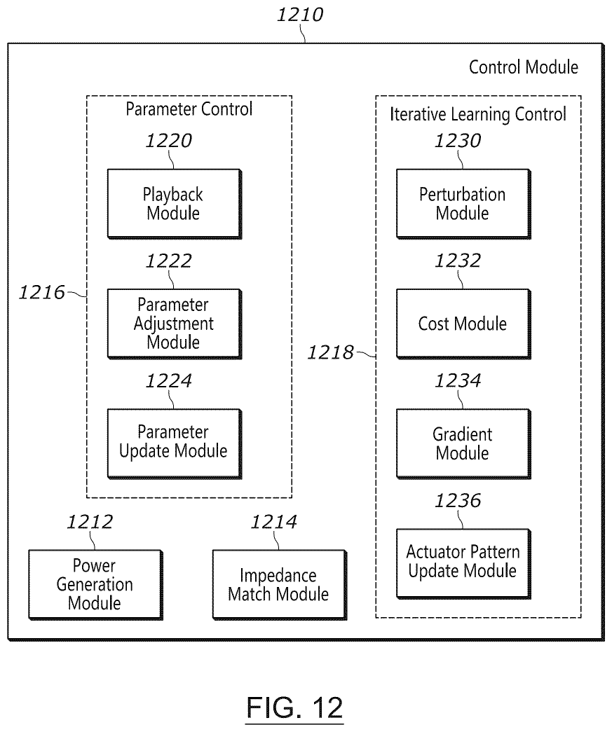

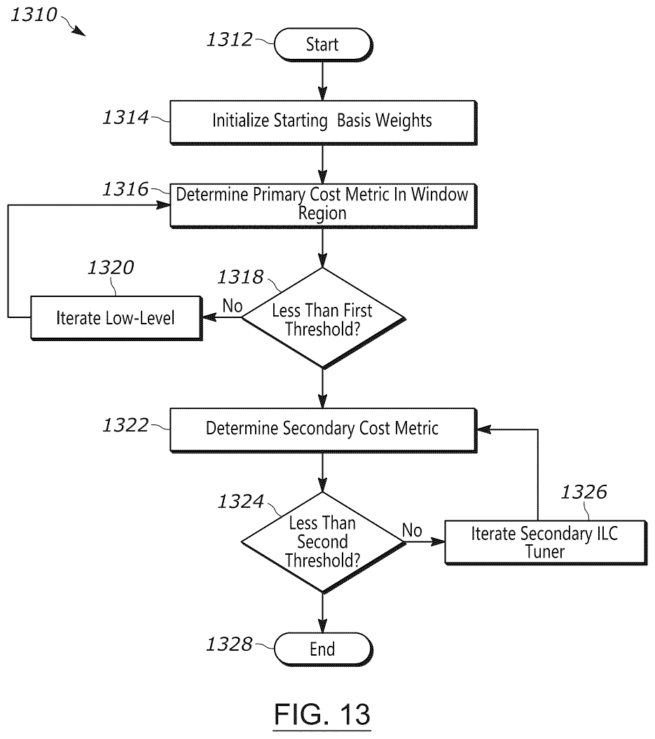

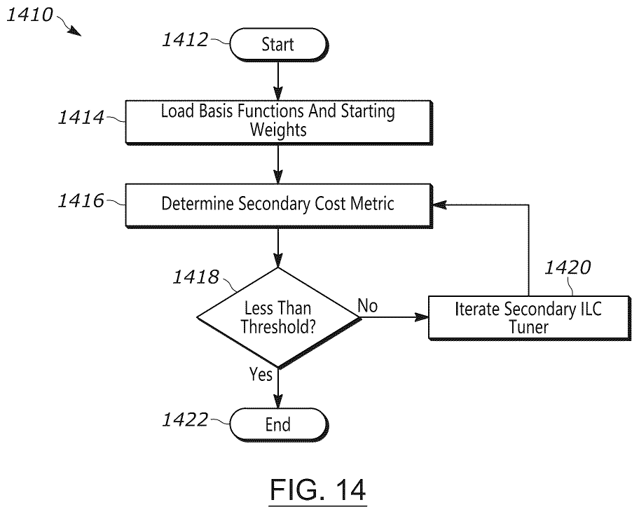

FIG. 12 shows a control module 1210. Control module 1210 incorporates various components of FIGS. 2-11. Control module 1210 may include power generation module 1212, impedance match module 1214, parameter control section 1216, and iterative learning control section 1218. Parameter control section 1212 includes playback module 1220, parameter adjustment module 1222, and parameter update module 1224. Iterative learning control section 1218 includes perturbation module 1230, cost module 1232, gradient module 1234, and actuator pattern update module 1236. In various embodiments, control module 1210 includes one or a plurality of processors that execute code associated with the module sections or modules 1212, 1214, 1216, 1218, 1220, 1222, 1224, 1230, 1232, 1234, and 1236. Operation of the module sections or modules 1212, 1214, 1216, 1218, 1220, 1222, 1224, 1230, 1232, 1234, and 1236 is described below with respect to the method of FIGS. 13 and 14.

For further defined structure of controllers 320a, 320b, and 320′ of FIG. 3, see the below provided flow chart of FIGS. 13 and 14 and the below provided definition for the term “module”. The systems disclosed herein may be operated using numerous methods, examples, and various control system methods of which are illustrated in FIG. 3. Although the following operations are primarily described with respect to the implementations of FIG. 3, the operations may be easily modified to apply to other implementations of the present disclosure. The operations may be iteratively performed. Although the following operations are shown and primarily described as being performed sequentially, one or more of the following operations may be performed while one or more of the other operations are being performed.

FIG. 13 shows a flow chart of a control system 1310 for performing primary layer and secondary (or N^{th}-ary control, where N=2 in this nonlimiting example) of a power generator, such as the power delivery system of FIG. 5. Control begins at 1312 and proceeds to 1314 where the starting basis weights are initialized, such as may be conventionally accomplished via a frequency offset or hopping pattern having peaks which are generally constant across the pulse state. Control proceeds to 1316 in which a primary cost metric is determined in a predetermined window region. Control proceeds to 1318 where it is determined whether the primary cost metric is less than a predetermined threshold. If the primary cost metric is greater than a first threshold, control proceeds to 1320 in which a primary or low-level tuner, such as an ILC tuner, iterates to update the frequency offset or hopping pattern waveform. From 1320, control returns to 1316 where the primary cost metric is again determined. Control then proceeds to 1318 in which the primary cost metric is compared to the first threshold. If the primary cost metric is less than the first threshold, control proceeds to 1322 were the secondary cost metric is determined. Control next proceeds to 1324 where it is determined whether the secondary cost metric is less than a second threshold. If the secondary cost metric is greater than the second threshold, control proceeds to 1326 in which a secondary or high-level tuner, such as an ILC tuner, iterates to update the frequency offset or hopping pattern waveform. Control returns to 1322 were the secondary cost metric is again determined and proceeds to 1324 where it is determined if the secondary cost metric is less than the second threshold. If the secondary cost metric is less than the second threshold, control terminates at 1328. The flowchart of FIG. 1310 can result in a frequency offset or hopping pattern waveform similar to that shown in FIG. 9.

As described above, primary or low-level tuning of basis weights may be learned in a training or characterization process determined off-line. Online tuning may then be carried out by the secondary or high-level tuner. FIG. 14 is a flowchart for tuning of the secondary or high-level basis weights. Control begins at 1412 and proceeds to 1414 in which the initial weights determined during the primary or low-level tuning that occurred during the training or characterization process are loaded and applied to generate a frequency offset or hopping pattern waveform. Control proceeds to 1416 where the secondary cost metric is determined. Control proceeds to 1418 which determines whether the secondary cost metric is less than a predetermined threshold. If the secondary cost metric is greater than the predetermined threshold, control proceeds to 1420, in which a secondary or high-level tuner, such as an ILC tuner, iterates to update the frequency offset or hopping pattern waveform. Control returns to 1416 which again determines the secondary cost metric and proceeds to 1418 which determines whether the determined cost metric is less than the predetermined threshold. If the determined cost metric is less than the predetermined threshold, control terminates at 1422.

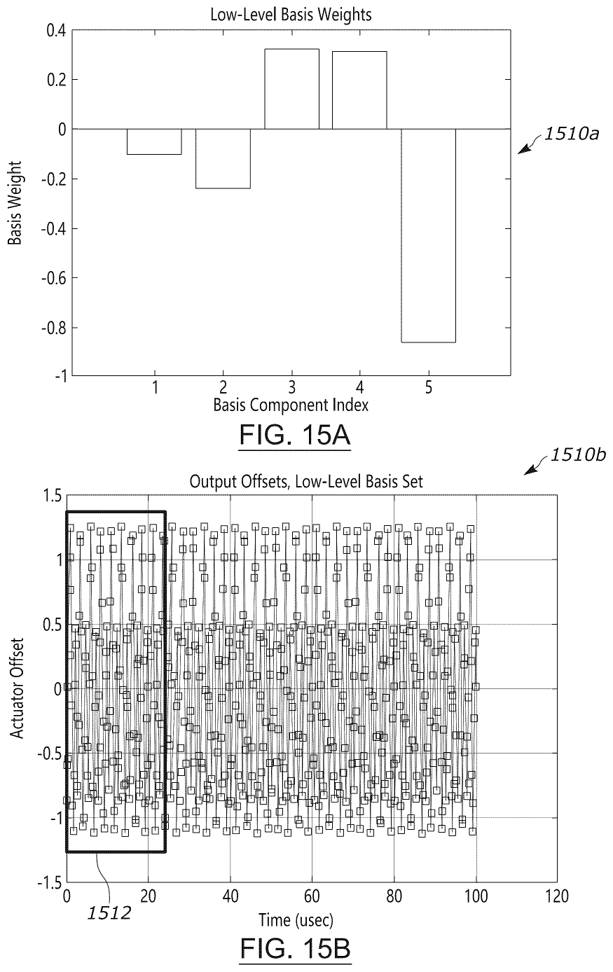

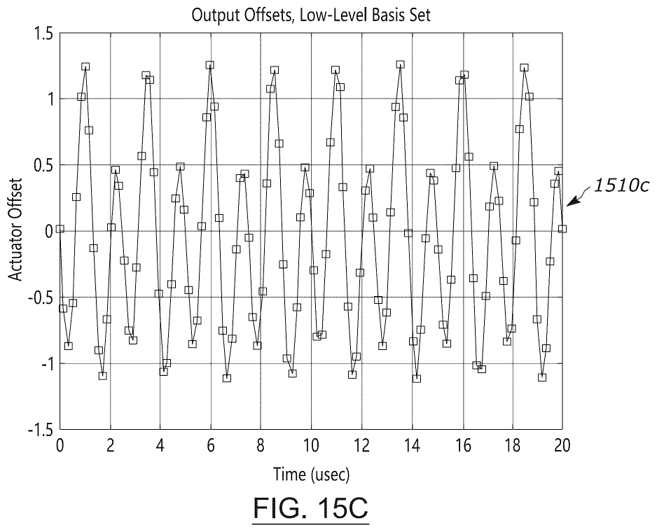

FIG. 15A-15C show an example primary or low-level basis function indexes and weights and its corresponding primary or low-level frequency offset or hopping pattern. FIG. 15A shows primary or low-level basis function indexes and weights 1510a, including Fourier basis component index and corresponding basis weights. FIG. 15B shows a frequency offset or hopping pattern waveform 1510b that corresponds to the low-level basis weights of FIG. 15A. FIG. 15C shows an expanded view of portion 1512 of frequency offset or hopping pattern waveform 1510b of FIG. 15B.

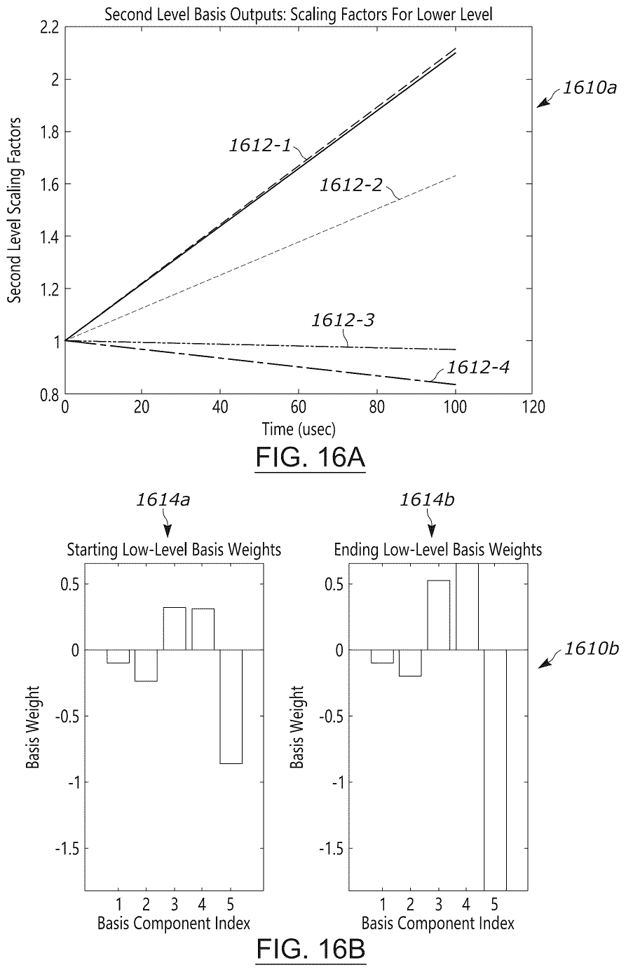

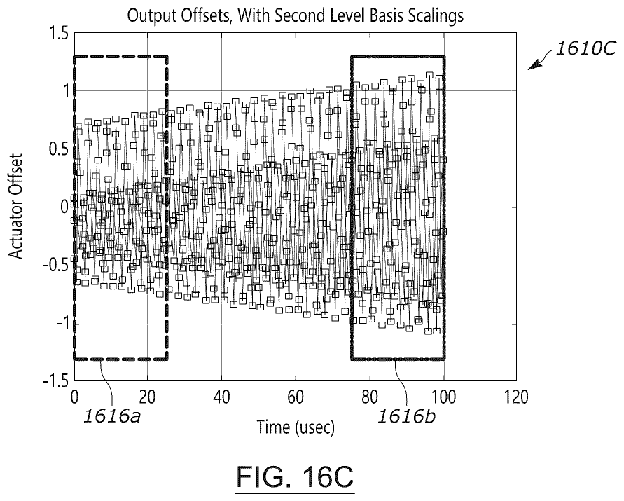

FIG. 16A-16C show example secondary or high-level basis function output scalings, scaled basis function indexes and weights, and corresponding secondary or high-level frequency offset or hopping pattern according to the present disclosure. FIG. 16A shows secondary or high-level basis function scaling factors, which represent scaling factors for the corresponding primary or low-level basis weights. FIG. 16A shows waveforms 1610a, including individual scaling factors 1612-1, 1612-2, 1612-3, and 1612-4, which correspond to a respective basis weight of FIG. 15A. FIG. 16B shows starting primary or low-level basis weights 1614a and ending primary or low-level basis weights 1614b, which correspond to the basis weights of FIG. 15A scaled by a respective scaling of FIG. 16A. As can be seen, basis component indexes 2, 3, 4, 5 of 1614a are scaled to have different weights for corresponding basis component indexes 2, 3, 4, 5 of 1614b. FIG. 16C shows frequency offset or hopping pattern waveform 1610c with offsets with secondary or high-level basis scaling the primary or low-level basis weights. Region 1616a corresponds to starting secondary or low-level basis weights 1614a, and region 1616b corresponds to ending secondary or low-level basis weights 1614b.

In various configurations, the present disclosure addresses within-pulse-state variability in IMD patterns. By providing an apparatus and method for tuning the frequency offset or hopping pattern dynamically across one or more pulse states, the present disclosure enables further reduction in the IMD effect. In various configurations, the present disclosure may be applicable to applications having narrow pulse widths where the transient nature of the pulse edges significantly impact the reflected power, because the generally steady-state portion of the pulse state is smaller for narrow pulse states. In various configurations, the present disclosure improves tracking during various plasma fabrication recipe steps, which may be particularly applicable when the pulse repetition rate is relatively low and the pulse duty cycle is also relatively low. In various configurations, the present disclosure may also be used in pulsed DC bias power supply IMD mitigation occurs across the pulse, which may be more challenging than when performing IMD mitigation across the bias cycle. In various configurations, the present disclosure enables multi-level feedforward adjustments for pulse shaping using ILC or other control approaches. By way of non-limiting example, the present disclosure enables applying ILC for pulse shaping by controlling one or both of drive or frequency actuators. Further, for various applications, the primary or low-level control might be applied across an entire pulse period, controlling all pulse states, while the secondary or higher-level control is applied over one or more recipe steps or process transitions spanning one or multiple pulse states, such as controlling a ramp between process recipe steps.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. In the written description and claims, one or more steps within a method may be executed in a different order (or concurrently) without altering the principles of the present disclosure. Similarly, one or more instructions stored in a non-transitory computer-readable medium may be executed in a different order (or concurrently) without altering the principles of the present disclosure. Unless indicated otherwise, numbering or other labeling of instructions or method steps is done for convenient reference, not to indicate a fixed order.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

The phrase “at least one of A, B, and C” should be construed to mean a logical (A OR B OR C), using a non-exclusive logical OR, and should not be construed to mean “at least one of A, at least one of B, and at least one of C.” The term “set” does not necessarily exclude the empty set—in other words, in some circumstances a “set” may have zero elements. The term “non-empty set” may be used to indicate exclusion of the empty set—in other words, a non-empty set will always have one or more elements. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” can be replaced with the term “controller” or the term “circuit.” In this application, the term “controller” can be replaced with the term “module.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); processor hardware (shared, dedicated, or group) that executes code; memory hardware (shared, dedicated, or group) that stores code executed by the processor hardware; other suitable hardware components that provide the described functionality; or a combination of some or all of the above, such as in a system-on-chip.

The module may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2020 (also known as the WIFI wireless networking standard) and IEEE Standard 802.3-2018 (also known as the ETHERNET wired networking standard). Examples of a WPAN are IEEE Standard 802.15.4 (including the ZIGBEE standard from the ZigBee Alliance) and, from the Bluetooth Special Interest Group (SIG), the BLUETOOTH wireless networking standard (including Core Specification versions 3.0, 4.0, 4.1, 4.2, 5.0, and 5.1 from the Bluetooth SIG).

The module may communicate with other modules using the interface circuit(s). Although the module may be depicted in the present disclosure as logically communicating directly with other modules, in various implementations the module may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module may be distributed among multiple modules that are connected via the communications system. For example, multiple modules may implement the same functionality distributed by a load balancing system. In a further example, the functionality of the module may be split between a server (also known as remote, or cloud) module and a client (or, user) module. For example, the client module may include a native or web application executing on a client device and in network communication with the server module.

Some or all hardware features of a module may be defined using a language for hardware description, such as IEEE Standard 1364-2005 (commonly called “Verilog”) and IEEE Standard 1076-2008 (commonly called “VHDL”). The hardware description language may be used to manufacture and/or program a hardware circuit. In some implementations, some or all features of a module may be defined by a language, such as IEEE 1666-2005 (commonly called “SystemC”), that encompasses both code, as described below, and hardware description.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

The memory hardware may also store data together with or separate from the code. Shared memory hardware encompasses a single memory device that stores some or all code from multiple modules. One example of shared memory hardware may be level 1 cache on or near a microprocessor die, which may store code from multiple modules. Another example of shared memory hardware may be persistent storage, such as a solid state drive (SSD), which may store code from multiple modules. Group memory hardware encompasses a memory device that, in combination with other memory devices, stores some or all code from one or more modules. One example of group memory hardware is a storage area network (SAN), which may store code of a particular module across multiple physical devices. Another example of group memory hardware is random access memory of each of a set of servers that, in combination, store code of a particular module.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of a non-transitory computer-readable medium are nonvolatile memory devices (such as a flash memory device, an erasable programmable read-only memory device, or a mask read-only memory device), volatile memory devices (such as a static random access memory device or a dynamic random access memory device), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. Such apparatuses and methods may be described as computerized apparatuses and computerized methods. The functional blocks and flowchart elements described above serve as software specifications, which can be translated into the computer programs by the routine work of a skilled technician or programmer.

The computer programs include processor-executable instructions that are stored on at least one non-transitory computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Swift, Haskell, Go, SQL, R, Lisp, Java®, Fortran, Perl, Pascal, Curl, OCaml, JavaScript®, HTML 5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A controller for a power generator comprising:
a power controller coupled to a power source, the power controller configured to generate a control signal to vary an output signal pulsed over a plurality of pulse states, the power controller configured to adjust at least one parameter of the output signal that determines a characteristic of the output signal for at least one pulse state,
wherein the at least one parameter is controlled with a primary adjustment and at least one secondary adjustment, wherein the at least one secondary adjustment varies the primary adjustment.

2. The controller of claim 1 wherein the at least one parameter is controlled in accordance with one of minimizing or maximizing a cost function responsive to adjustment of the at least one parameter, wherein the at least one parameter includes at least one of frequency, voltage, or impedance.

3. The controller of claim 1 wherein the at least one secondary adjustment varies the primary adjustment:
within a selected pulse state for each a plurality of adjacent pulse states;
within a selected pulse state for each of a plurality of nonadjacent pulse states;
over a plurality of pulse states adjacent pulse states; or
over a plurality of nonadjacent pulse states.

4. The controller of claim 3 wherein the at least one secondary adjustment may be the same for a plurality of selected pulse states, or the at least one secondary adjustment may be different for each of a plurality of selected pulse states.

5. The controller of claim 1 wherein the at least one secondary adjustment further comprises a plurality of secondary adjustments, wherein:
the plurality of secondary adjustments varies the primary adjustment within a selected pulse state; or
the plurality of secondary adjustments varies the primary adjustment over a plurality of pulse states.

6. The controller of claim 1 wherein the primary adjustment is formed by a first basis set and the at least one secondary adjustment is formed by a second basis set.

7. The controller of claim 6 wherein the power source provides an output signal that may be one of a sinusoidal signal, square wave signal, rectangular wave signal, triangular signal, gaussian signal, piecewise linear signal, narrow pulse voltage peak followed by a ramp down signal, or an arbitrary signal.

8. A power generator system comprising:
a power source, the power source generating a time-varying output signal to a load;
a power controller coupled to the power source, the power controller configured to generate a control signal to vary an output signal pulsed over a plurality of pulse states, the power controller configured to adjust at least one parameter of the output signal that determines a characteristic of the output signal for at least one pulse state;
a primary tuner configured to provide a first adjustment to the at least one parameter, and
at least one secondary tuner configured to apply at least one second adjustment to the first adjustment,
wherein the at least one parameter is adjusted by the primary tuner and the at least one secondary tuner in accordance with one of minimizing or maximizing a cost function responsive to adjustment of the at least one parameter.

9. The power generator system of claim 8 wherein the at least one secondary tuner varies applies at least one second adjustment:
within a selected pulse state for each of a plurality of adjacent pulse states;
within a selected pulse state for each of a plurality of nonadjacent pulse states;
over a plurality of pulse states adjacent pulse states; or
over a plurality of nonadjacent pulse states.

10. The power generator system of claim 9 wherein the at least one secondary tuner may apply a same at least one second adjustment to a plurality of selected pulse states, or the at least one secondary tuner may apply a different at least one second adjustment for each of the plurality of selected pulse states.

11. The power generator system of claim 8 wherein the at least one secondary tuner further applies a plurality of at least one second adjustments, wherein:
the plurality of at least one second adjustments varies the first adjustment within a selected pulse state; or
the plurality of at least one second adjustments varies the first adjustment over a plurality of pulse states.

12. The power generator system of claim 8 wherein the first adjustment is formed from a first basis set and the at least one second adjustment is formed by at least one second basis set.

13. The power generator system of claim 12 wherein the power source provides an output signal that may be one of a sinusoidal signal, square wave signal, rectangular wave signal, triangular signal, gaussian signal, piecewise linear signal, narrow pulse voltage peak followed by a ramp down signal, or an arbitrary signal.

14. A non-transitory computer-readable medium storing instructions, the instructions comprising:
generating a control signal to vary an output signal pulsed over a plurality of pulse states; and
adjusting at least one parameter of the output signal that determines a characteristic of the output signal for at least one pulse state;
controlling the at least one parameter with a primary adjustment; and
further controlling the at least one parameter with at least one secondary adjustment, wherein the at least one secondary adjustment varies the primary adjustment.

15. The non-transitory computer-readable medium storing instructions of claim 14 wherein the at least one parameter is controlled in accordance with one of minimizing or maximizing a cost function responsive to adjustment of the at least one parameter, wherein the at least one parameter includes at least one of frequency, voltage, or impedance.

16. The non-transitory computer-readable medium storing instructions of claim 14 wherein the at least one secondary adjustment varies the primary adjustment:
within a selected pulse state for each a plurality of adjacent pulse states;
within a selected pulse state for each of a plurality of nonadjacent pulse states;
over a plurality of pulse states adjacent pulse states; or
over a plurality of nonadjacent pulse states.

17. The non-transitory computer-readable medium storing instructions of claim 13 wherein the at least one secondary adjustment may be the same for a plurality of selected pulse states, or the at least one secondary adjustment may be different for each of a plurality of selected pulse states.

18. The non-transitory computer-readable medium storing instructions of claim 14 wherein the at least one secondary adjustment further comprises a plurality of secondary adjustments, wherein:
the plurality of secondary adjustments varies the primary adjustment within a selected pulse state; or
the plurality of secondary adjustments varies the primary adjustment over a plurality of pulse states.

19. The non-transitory computer-readable medium storing instructions of claim 14 wherein the primary adjustment is formed by a first basis set and the at least one secondary adjustment is formed by a second basis set.

20. The non-transitory computer-readable medium storing instructions of claim 19 wherein the power source provides an output signal that may be one of a sinusoidal signal, square wave signal, rectangular wave signal, triangular signal, gaussian signal, piecewise linear signal, narrow pulse voltage peak followed by a ramp down signal, or an arbitrary signal.
